(19) United States
(12) Patent Application Publication
(10) Pub. No.: US 2009/0310799 A1
(43) Pub. Date: Dec. 17, 2009

(54) INFORMATION PROCESSING APPARATUS AND METHOD, AND PROGRAM

(76) Inventors: Shiro SUZUKI, Kanagawa (JP); Akira Inoue, Tokyo (JP); Chisato Kemmochi, Kanagawa (JP); Shusuke Takahashi, Chiba (JP)

Correspondence Address: FINNEGAN, HENDERSON, FARABOW,;GARRETT & DUNNER, L.L.P., 901 New York Avenue, NW, Washington, DC, 20001-4413, US

(21) Appl. No.: 12/480,324

(22) Filed: Jun. 8, 2009

(30) Foreign Application Priority Data
Jun. 13, 2008 (JP) 2008-154837

(51) Int. Cl. H03G 5/00

(52) U.S. Cl. 381/98

(57) ABSTRACT

An information processing apparatus includes a band spreading unit configured to perform a band spreading process for generating components in a specific frequency band and adding the components to audio data, and a control unit configured to control the band spreading unit to execute the band spreading process using a band spreading method determined among a plurality of different band spreading methods, the band spreading method being defined in advance for a musical class determined using a feature of the audio data.

### BACKGROUND OF THE INVENTION

1. Field of the Invention

The present invention relates to an information processing apparatus and method, and a program. More specifically, the present invention relates to an information processing apparatus and method, and a program suitable for use in the playback of encoded audio data.

2. Description of the Related Art

When audio data of musical pieces is encoded using an existing generalized encoding scheme (compression scheme) such as Adaptive Transform Acoustic Coding (ATRAC) or Moving Picture Experts Group Audio Layer-3 (MP3), high-frequency components may be lost. Lack of the high-frequency components may cause muffled sound when a musical piece is played back and the richness of sound may be reduced.

When audio data of a musical piece is encoded, as shown in FIG. 1, first, a frequency conversion unit 11 in an encoder converts audio data having a time waveform into individual frequency components of the musical piece, that is, frequency information indicating the powers of individual frequencies. Then, a quantization unit 12 quantizes the frequency information into quantized information. Further, an encoding unit 13 encodes the quantized information and outputs resulting code strings as encoded audio data. The audio data having a time waveform refers to data indicating the amplitudes (gains) of audio at different times.

The audio data encoded in the manner described above is decoded and played back by a decoder during playback of the musical piece. Specifically, a decoding unit 14 decodes the audio data into quantized information, and a dequantization unit 15 dequantizes the quantized information into frequency information. Then, a time conversion unit 16 converts the frequency information into audio data having a time waveform. The resulting audio data is output as decoded audio data.

When audio data is encoded, high-frequency components of musical pieces included in frequency information are generally cut (removed) for data compression. Since high-frequency sound is less perceived by the human ear, there is less influence of data removal.

However, if high-frequency components are removed from audio data, frequency information output from the frequency conversion unit 11 and frequency information output from the dequantization unit 15 are not identical. For example, as shown in FIG. 2, high-range components (high-frequency components) of a musical piece are cut by encoding.

In FIG. 2, the vertical axis represents the amplitude of audio, or frequency power, of a musical piece and the horizontal axis represents time or frequency.

When audio data of audio having a time waveform shown in an upper part of FIG. 2 is frequency-converted, frequency information shown in a middle left part of FIG. 2 is obtained. This frequency information contains components at different frequencies ranging from low-range components to high-range components. If the high-range components in the frequency information are removed during the encoding of the audio data, as shown in a middle right part of FIG. 2, frequency information obtained during decoding contains no high-range components. In other words, the frequency information shown in the middle right part of FIG. 2 contains only low-range components.

Thus, when the frequency information obtained by dequantization performed by the dequantization unit 15 is time-converted, as shown a lower part of FIG. 2, audio data of audio is obtained whose time waveform is rounder than that of the original audio before encoding. In this manner, the time waveform of audio based on audio data obtained by decoding is round because the high-range components (high-frequency components) contained in the original audio data have been removed.

When a musical piece is played back using audio data from which the high-range components have been removed in the manner described above, the played back musical piece may sound muffled even if the original musical piece has rich sound. The level to which the musical piece played back sounds muffled depends on the amount by which the high-range components have been removed.

It is said that the upper limit of the human audible frequency range is on the order of about 20 kHz. Most people do not feel that sound is muffled when played back if the frequency components up to about 15 kHz are contained in the audio data. Although there are differences between ages and individuals, in general, most adults can experience a muffled-sound feeling when audio, is played back if the audio data contains only components at frequencies of about 11 kHz or less.

This is better described using an example where people have substantially no muffled-sound feeling for frequency modulation (FM) broadcasting services that use signals containing frequency components up to about 15 kHz while most people have a muffled-sound feeling when they listen to amplitude modulation (AM) broadcasting services that use signals containing only frequency components up to about 8 kHz.

There has been available a technique called band spreading (see, for example, Japanese Unexamined Patent Application Publication No. 2007-328268) which can improve the richness of sound, when played back, by generating high-range components of audio data, which are lost during encoding, and adding the high-range components to the audio data during playback of audio.

For example, in a music playback apparatus that adopts the band spreading technique, as shown in FIG. 3, audio data supplied from a decoder is subjected to a band spreading process using a band spreading unit 41. Specifically, the band spreading unit 41 uses decoded audio data supplied from a time conversion unit 16 and generates high-range components of the audio data. Then, the band spreading unit 41 adds the generated high-range components to the audio data to produce final audio data, and outputs the produced audio data. In FIG. 3, portions corresponding to those shown in FIG. 1 are assigned the same reference numerals and the description thereof is omitted.

For example, if the audio data supplied from the time conversion unit 16 in the decoder to the band spreading unit 41 contains no high-range components, as shown in an upper part of FIG. 4, audio based on this audio data is audio whose time waveform is round and slightly changes with time. In FIG. 4, the vertical axis represents the amplitude of audio, or frequency power, and the horizontal axis represents time or frequency.

When audio data of audio having the time waveform shown in the upper part of FIG. 4 is supplied to the band spreading unit 41, the band spreading unit 41 performs frequency analysis on the supplied audio data to generate high-range components. Specifically, as shown in a middle left part of FIG. 4, the band spreading unit 41 duplicates low-range components SL′ of the audio data and generates high-range components SH′ to be added to the audio data. Further, as shown in a middle right part of FIG. 4, the band spreading unit 41 adjusts the shape of the generated high-range components SH′ to produce final high-range components XSH′.

The band spreading unit 41 adds the high-range components XSH′ generated in the manner described above to the audio data supplied from the time conversion unit 16. Therefore, as shown in a lower part of FIG. 4, audio data of audio having a time waveform that largely changes with time, that is, audio data having high-range components, is obtained. Thus, the quality of audio to be played back can be improved.

Three band spreading methods can be conceived as specific methods for performing a band spreading process in which the band spreading unit 41 generates high-range components of audio and adds the high-range components to audio data: a method for performing band spreading along the frequency axis, a method for performing band spreading along the time axis, and a method for performing band spreading along both the time axis and the frequency axis.

In the method for performing band spreading along the frequency axis among the above three band spreading methods, as shown in FIG. 5A, audio data is converted into frequency information, and high-range components are generated using the frequency information obtained by conversion. Then, the generated high-range components are added to the frequency information, and the resulting frequency information is time-converted to obtain band-spread audio data having a time waveform.

Specifically, a frequency conversion unit 71 frequency-converts decoded audio data to convert audio data into frequency information. A duplication generation unit 72 uses the frequency information and generates high-range components to be added to audio. A shape adjustment unit 73 modifies the high-range components to change the powers of the individual frequency components, and adjusts the shape of the high-range components.

Further, a high-range attachment unit 74 attaches the shape-adjusted high-range components to the frequency information, and supplies the resulting frequency information to a time conversion unit 75. Then, the time conversion unit 75 performs time conversion to convert the frequency information to which the high-range components have been attached, that is, the frequency information to which the high-range components have been added, into audio data indicating the amplitudes of audio at different times, and outputs the audio data. The method for performing band spreading along the frequency axis, or in the frequency domain, is hereinafter referred to as “band spreading using the frequency-based band spreading scheme”.

In the method for performing band spreading along the time axis, as shown in FIG. 5B, low-range components extracted from supplied audio data using a split filter unit 81 are modified to generate high-range components. Then, the supplied audio data and audio data of the generated high-range components are combined using a combination filter unit 84. Thus, band-spread audio data is obtained.

Specifically, the split filter unit 81 splits decoded audio data into frequency bands using a split filter, and extracts low-range components and high-range components of audio from the audio data. Note that the decoded audio data contains substantially no high-range components. Therefore, the split filter extracts substantially no high-range components from the audio data, which are represented by a cross (“x”) mark in FIG. 5B because they are not usable in the subsequent stages.

A duplication generation unit 82 uses audio data of the low-range components extracted by the split filter unit 81 and generates audio data of high-range components to be added to audio. A shape adjustment unit 83 modifies the generated audio data of the high-range components, and adjusts the shape of the high-range components. Then, the combination filter unit 84 combines the frequency bands of the audio data of the low-range components extracted by the split filter unit 81 and the audio data of the shape-adjusted high-range components using a combination filter, and outputs resulting audio data as band-spread audio data. The method for performing band spreading along the time axis, or in the time domain, is hereinafter referred to as “band spreading using the time-based band spreading scheme”.

In the method for performing band spreading along both the time axis and the frequency axis, as shown in FIG. 5C, low-range components are extracted from audio data using a split filter unit 91, and the low-range components are converted into frequency information. High-range components are generated using the frequency information obtained by conversion. Then, the generated high-range components and the low-range components are converted into audio data using time conversion, and resulting two pieces of audio data are combined. Thus, band-spread audio data having a time waveform is obtained.

Specifically, the split filter unit 91 splits decoded audio data into frequency bands using a split filter, and extracts low-range components of audio from the audio data.

A frequency conversion unit 92 performs frequency conversion to convert audio data of the extracted low-range components into frequency information. A duplication generation unit 93 uses the frequency information and generates high-range components to be added to audio. A shape adjustment unit 94 adjusts the shape of the generated high-range components.

A time conversion unit 95 performs time conversion to convert the shape-adjusted high-range components into audio data indicating the amplitudes of audio at different times. A time conversion unit 96 performs time conversion to convert the frequency information supplied from the frequency conversion unit 92 into audio data. A combination filter unit 97 combines the frequency band of the audio data supplied from the time conversion unit 95 with the frequency band of the audio data supplied from the time conversion unit 96 using a combination filter, and outputs resulting audio data as band-spread audio data. The method for performing band spreading along both the time axis and the frequency axis, or in both the time domain and the frequency domain, is hereinafter referred to as “band spreading using the time/frequency-based band spreading scheme”.

### SUMMARY OF THE INVENTION

In a music playback apparatus of the related art having a band spreading function, audio data is subjected to band spreading using a predetermined band spreading scheme and audio is played back. However, depending on the audio data to be subjected to band spreading, improvement in sound quality is not necessarily achievable.

The band spreading technique is a technique for estimating high-range components (high-frequency components) which are lost in audio based on audio data, generating estimated high-range components in a pseudo-manner, and adding the generated high-range components to the original audio. Due to the nature of the technique, high-range components originally contained in audio may not necessarily be obtained. Conversely, as a result of band spreading, unwanted noise may be added to audio.

In a band spreading method of the related art, accordingly, the effect of improving the quality of audio may or may not be obtained depending on the features of audio based on audio data. Thus, it is difficult to reliably improve the quality of audio regardless of the features of audio data.

It is therefore desirable to more reliably improve the quality of audio.

According to an embodiment of the present invention, an information processing apparatus includes band spreading means for performing a band spreading process for generating components in a specific frequency band and adding the components to audio data, and control means for controlling the band spreading means to execute the band spreading process using a band spreading method determined among a plurality of different band spreading methods, the band spreading method being defined in advance for a musical class determined using a feature of the audio data.

The band spreading means may perform a band spreading process for generating components in the specific frequency band based on audio data obtained by decoding encoded audio data and adding the components to the audio data.

The plurality of different band spreading methods may include at least a band spreading method for performing the band spreading process along a time axis, a band spreading method for performing the band spreading process along a frequency axis, and a band spreading method for performing the band spreading process along the time axis and the frequency axis.

The audio data may be data for playing back a musical piece, and the information processing apparatus may further include classifying means for classifying the musical piece into one of a plurality of musical classes based on audio data of the musical piece, the plurality of musical classes being determined in advance using features of musical pieces.

The band spreading means may include generating means for generating components in the specific frequency band using the audio data, and adjusting means for increasing or decreasing each of frequency components in the specific frequency band. The control means may control the adjusting means to increase or decrease each of the frequency components using an adjustment method determined among a plurality of adjustment methods for adjusting the components in the specific frequency band, the adjustment method being determined in advance in accordance with a classification result obtained by the classifying means.

The control means may control the generating means to generate components in the specific frequency band using a generation method determined among a plurality of generation methods for generating components in the specific frequency band, the generation method being determined in advance in accordance with the classification result.

The information processing apparatus may further include recording means for recording, for each of the plurality of musical classes, information indicating a combination of methods that is assigned in advance a highest evaluation among a plurality of combinations of methods, the plurality of combinations of methods including the plurality of band spreading methods, the plurality of generation methods, and the plurality of adjustment methods. The band spreading method, the generation method, and the adjustment method may be selected using the classification result and the recorded information, and the control means may control the band spreading means to perform the band spreading process using the selected band spreading method, generation method, and adjustment method.

The evaluation may be obtained by statistically processing an objective evaluation result and a subjective evaluation result, the objective evaluation result being obtained by performing analysis of audio data obtained using the band spreading process.

According to an embodiment of the present invention, an information processing method for an information processing apparatus includes the steps of performing a band spreading process for generating components in a specific frequency band and adding the components to audio data, and performing control to execute the band spreading process using a band spreading method determined among a plurality of different band spreading methods, the band spreading method being defined in advance for a musical class determined using a feature of the audio data. According to an embodiment of the present invention, a program for causing a computer of an information processing apparatus to execute a process including the above steps.

According to an embodiment of the present invention, a band spreading process can be executed by band spreading means using a band spreading method determined among a plurality of different band spreading methods. The band spreading method can be defined in advance for a musical class determined using a feature of audio data.

In an embodiment of the present invention, band spreading can be performed on audio data. More specifically, in an embodiment of the present invention, the quality of audio can be more reliably improved.

### BRIEF DESCRIPTION OF THE DRAWINGS

FIG. 1 is a diagram showing a structure of an encoder and decoder of the related art;

FIG. 2 is a diagram describing lack of high-range components which occurs during encoding in the related art;

FIG. 3 is a diagram describing band spreading of the related art;

FIG. 4 is a diagram describing band spreading of the related art;

FIGS. 5A to 5C are diagrams showing structures of a band spreading unit of the related art for performing band spreading;

FIG. 6 is a diagram showing evaluations given to combinations of band spreading methods, high-range-component generation methods, and shape adjustment methods;

FIG. 7 is a block diagram showing an example structure of an audio playback apparatus according to an embodiment of the present invention;

FIG. 8 is a diagram showing an example structure of a correction unit;

FIG. 9 is a flowchart describing a playback process;

FIG. 10 is a flowchart describing a process of playing back a musical piece subjected to a band spreading process based on a frequency-based band spreading scheme;

FIG. 11 is a flowchart describing a process of playing back a musical piece subjected to a band spreading process based on a time-based band spreading scheme;

FIG. 12 is a flowchart describing a process of playing back a musical piece subjected to a band spreading process based on a time/frequency-based band spreading scheme;

FIG. 13 is a diagram showing another example structure of the correction unit;

FIG. 14 is a flowchart describing a playback process; and

FIG. 15 is a diagram showing an example structure of a computer.

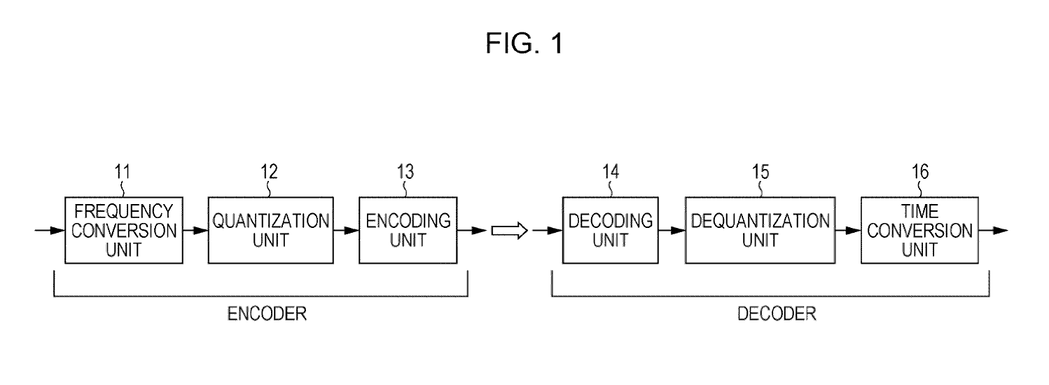

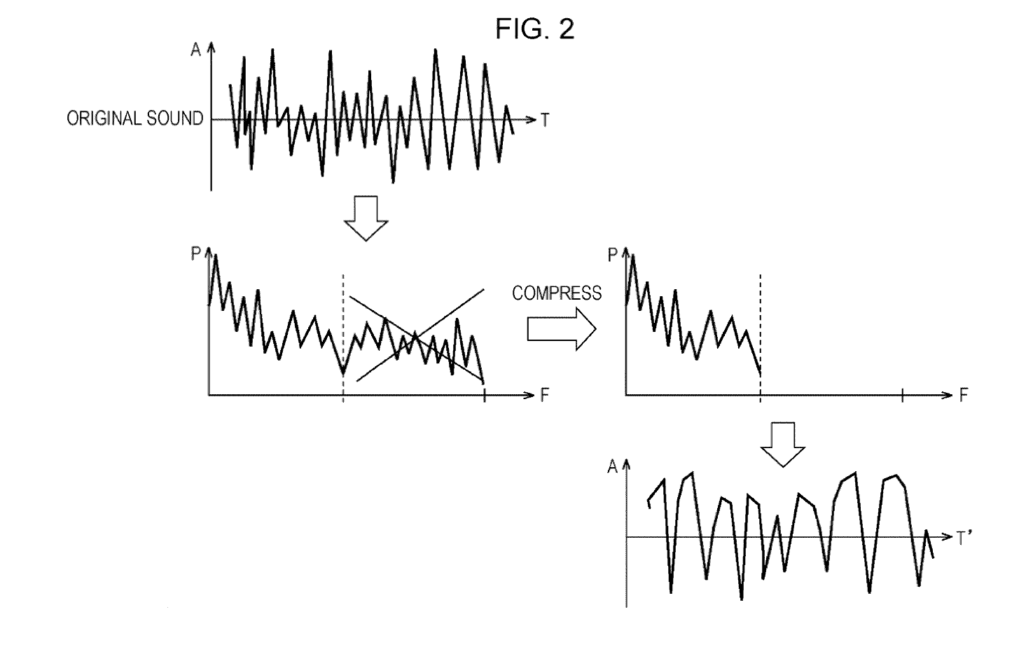

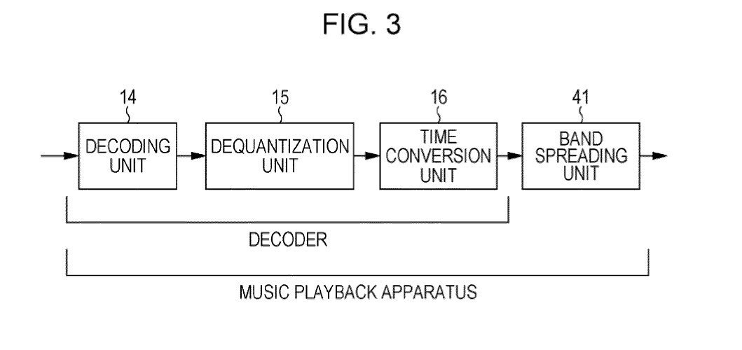

### DESCRIPTION OF THE PREFERRED EMBODIMENTS

Embodiments of the present invention will be described hereinafter with reference to the drawings.

An audio playback apparatus according to an embodiment of the present invention is configured to classify audio to be subjected to band spreading in accordance with the features of the audio, select a desired band spreading scheme in accordance with the classification result, and perform a band spreading process on audio data using the selected band spreading scheme.

For example, if audio to be subjected to band spreading is a musical piece, the classification of the audio is performed by preparing in advance a plurality of musical classes, each of which is a group to which musical pieces having specific features belong, and classifying the audio to be subjected to band spreading into one of the plurality of prepared musical classes in accordance with the features of the audio.

The audio playback apparatus may be configured to not only change a band spreading scheme in accordance with the classification result of audio but also change a method for generating high-range components to be added to audio data (hereinafter referred to as a “high-range-component generation method”) and a method of adjusting the shape of the high-range components (hereinafter referred to as a “high-range-component shape adjustment method” or “shape adjustment method”) in accordance with the classification result. The term “high-range-component shape adjustment method” refers to a rule under which the magnitudes of frequency components serving as high-range components are increased or decreased, that is, a method of changing the frequency components.

Examples of the high-range-component generation method include a method in which components in a specific frequency band of audio based on audio data are folded back along the frequency axis and then shifted (translated) to produce high-range components (hereinafter referred to as a “fold-back scheme”), and a method in which components in a specific frequency band of audio are shifted as they are along the frequency axis to produce high-range components (hereinafter referred to as a “translating scheme”).

Specifically, for example, it is assumed that an audio signal including frequency components at frequencies of 0 kHz to 20 kHz is obtained using the fold-back scheme or the translating scheme. The frequency components are equally divided into two parts: frequency components of 0 kHz to 10 kHz which are referred to as “low-range components” and frequency components of 10 kHz to 20 kHz which are referred to as “high-range components”. In the following description, components at frequencies of 0 kHz to 10 kHz (hereinafter referred to as “low-range components”) are used to generate components at frequencies of 10 kHz to 20 kHz as high-range components.

In this case, in the fold-back scheme, the respective frequency components of 0 kHz to 10 kHz, which are the low-range components of audio, are used as the respective frequency components of 20 kHz to 10 kHz in the high-range components to be generated. Specifically, the low-range components are axisymmetrically folded back along the frequency axis so that the magnitude of a component having a low frequency in the low-range components becomes equal to the magnitude of a component having a high frequency in the high-range components.

Further, in the translation scheme, the respective frequency components of 0 kHz to 10 kHz, which are the low-range components of audio, are use as the respective frequency components of 10 kHz to 20 kHz in the high-range components to be generated. Specifically, the low-range components are directly translated to the high-frequency range along the frequency axis to produce high-range components so that the magnitude of a component having a low frequency in the low-range components become equal to the magnitude of a component having a low frequency in the high-range components.

Different high-range-component generation methods are used depending on, for example, which frequency band within the range of frequencies of audio is to be used to generate high-range components.

Further, examples of high-range-component shape adjustment methods include a method in which in accordance with the gradient in frequency information of audio based on audio data, that is, in accordance with the spectral shape of the audio, high-range components are extrapolated to the audio (hereinafter referred to as an “extrapolation scheme”), and a method in which in accordance with the features of low-range components of audio, high-range components are modified into a predetermined shape and are inserted into the audio (hereinafter referred to as a “learning scheme”).

In the extrapolation scheme, the shape of the high-range components is adjusted so as to meet the relationship between individual frequencies of audio to be subjected to band spreading and the powers of the frequencies, that is, the shape of the gradient of the power profile with respect to the frequencies in the frequency information. Specifically, for example, when the power of a frequency of audio, that is, the magnitude (amount) of a frequency component, decreases as the frequency increases, the shape of a high-range component to be added is adjusted so that the power can be reduced as the frequency increases.

In the learning scheme, high-range components originally contained in audio are learned in advance by performing a statistical process using the powers of a low-frequency range included in the audio, for example, the powers of the frequencies in a frequency band from 0 kHz to 10 kHz, that is, the spectral shape of the audio. That is, an average spectral shape of high-range components is determined using some audio models having different spectral shapes of the low-frequency range.

During shape adjustment using the learning scheme, an audio model having a spectral shape that is the closest to the spectral shape of the audio to be subjected to band spreading is selected using pattern matching. Further, high-range components whose shape is to be adjusted is subjected to shape adjustment so that the spectral shape of the high-range components whose shape is to be adjusted, that is, the relative magnitudes of the powers of the respective frequencies serving as the high-range components, coincides with a predetermined spectral shape of high-range components which is defined in advance for the selected model.

In the following, for simplicity of description, it is assumed that audio data to be subjected to band spreading is audio data for playing back a musical piece.

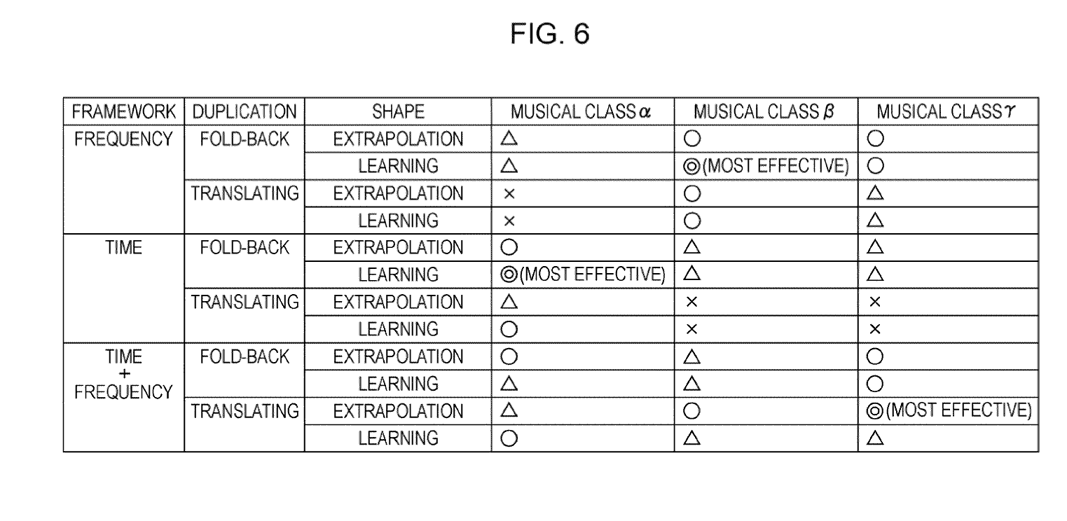

The audio playback apparatus is configured such that a band spreading method, a high-range-component generation method, and a shape adjustment method, which are the most effective to improve sound quality, are selected in accordance with a musical class of a musical piece (audio) based on audio data and band spreading is performed on the musical piece using the selected methods. In this case, for example, as shown in FIG. 6, various combinations of the above methods are evaluated in advance for each musical class.

In FIG. 6, each of musical classes α, β, and γ of musical pieces (audio) is given an evaluation value for combinations of the band spreading methods, the high-range-component generation methods, and the shape adjustment methods. Here, four levels of evaluation are adopted for evaluating the combinations, which are indicated by the symbols: double circle, circle (round shape), triangle, and cross in the descending order from the highest level of evaluation. That is, the symbol double circle represents the highest level of evaluation.

Further, the “framework” column contains band spreading methods, the characters “frequency”, “time”, and “time+frequency” represent the frequency-based band spreading schemes, the time-based band spreading schemes, and the time/frequency-based band spreading schemes, respectively. Further, the “duplication” column contains high-range-component generation methods, and the characters “fold-back” and “translating” represent the fold-back scheme and the translating scheme, respectively. Further, the “shape” column contains high-range-component shape adjustment methods, and the characters “extrapolation” and “learning” represent the extrapolation scheme and the learning scheme, respectively.

For example, for audio data of a musical piece belonging to the musical class a, band spreading using the combination of the time-based band spreading scheme, the fold-back scheme, and the learning scheme is the most effective to improve the sound quality. Similarly, for example, for audio data of a musical piece belonging to the musical class β, band spreading using the combination of the frequency-based band spreading scheme, the fold-back scheme, and the learning scheme is the most effective to improve the sound quality.

When the combinations of the above methods for each musical class are evaluated, for example, first, each of musical pieces to be subjected to band spreading is classified into one of a plurality of predetermined musical classes using some method. Then, a plurality of combinations of the band spreading methods, the high-range-component generation methods, and the shape adjustment methods are selected for each musical class, and band spreading is performed on musical pieces belonging to each musical class using the combinations. Thus, the combinations of the respective methods are evaluated.

For example, evaluation results obtained by performing analysis on audio data using an analyzer or calculator to objectively (quantitatively) evaluate the combinations of the respective methods and evaluation results obtained by subjectively evaluating the combinations of the respective methods by a person who actually listens to band-spread musical pieces are statistically processed to determine final evaluation values of the combinations of the respective methods.

In the example shown in FIG. 6, therefore, the most suitable combination of the methods, that is, the combination of a band spreading method, a high-range-component generation method, and a shape adjustment method, which is the most effective to improve sound quality, differs from musical class to musical class. Evaluations of band-spread musical pieces which are classified into the respective musical classes are different depending on the combination of the band spreading methods, high-range-component generation methods, and shape adjustment methods because each method (scheme) has different advantages and disadvantages.

For example, in the frequency-based band spreading scheme, it is possible to study in detail, using frequency conversion, which frequency components are contained in each musical piece, and there is an advantage of providing high prediction accuracy of high-range components. In other words, the frequency-based band spreading scheme has a high frequency resolution.

However, the frequency-based band spreading scheme has a disadvantages. Specifically, in the frequency-based band spreading scheme, high-range components are generated by, instead of directly using audio data having a time waveform, converting the audio data into frequency information. Thus, the generated high-range components have no information regarding time. Even when the frequency information serving as the high-range components is converted into audio data having a time waveform, for example, the time waveform of audio played back with the obtained high-range components may be mismatched with the time waveform of the high-range components of the original musical piece. That is, the temporal change in the amplitude of audio of the high-range components may be incorrectly reproduced. In other words, the frequency-based band spreading scheme has low time resolution of high-range components.

In contrast, in the time-based band spreading scheme, high-range components are generated by directly using audio data having a time waveform. Thus, high-range components whose temporal change matches the temporal change in the low-range components of the musical piece can be generated, and, advantageously, the time resolution is high. However, the time-based band spreading scheme does not allow detailed study of which frequency components are contained in each musical piece, and provides low prediction accuracy of high-range components. In other words, the frequency resolution is low.

Meanwhile, the time/frequency-based band spreading scheme can achieve the advantages of both the frequency-based band spreading scheme and the time-based band spreading scheme at the same time. However, conversely, the time/frequency-based band spreading scheme may suffer from the disadvantages of the two schemes at the same time. In other words, the time/frequency-based band spreading scheme has high frequency resolution and time resolution to some extent. The levels of the frequency resolution and the time resolution depend on the musical piece to be subjected to band spreading.

The audio playback apparatus records in advance a band-spreading matching database including musical classes and information determined in advance in the manner described above. The information indicates a combination of a band spreading method, a high-range-component generation method, and a shape adjustment method, which is the most effective for each of the musical classes to improve sound quality. The audio playback apparatus performs band spreading on audio data on the basis of the recorded band-spreading matching database.

Next, an example where the audio playback apparatus selects a desired band spreading scheme in accordance with a classification result of a musical piece and performs band spreading using the selected band spreading scheme will be described.

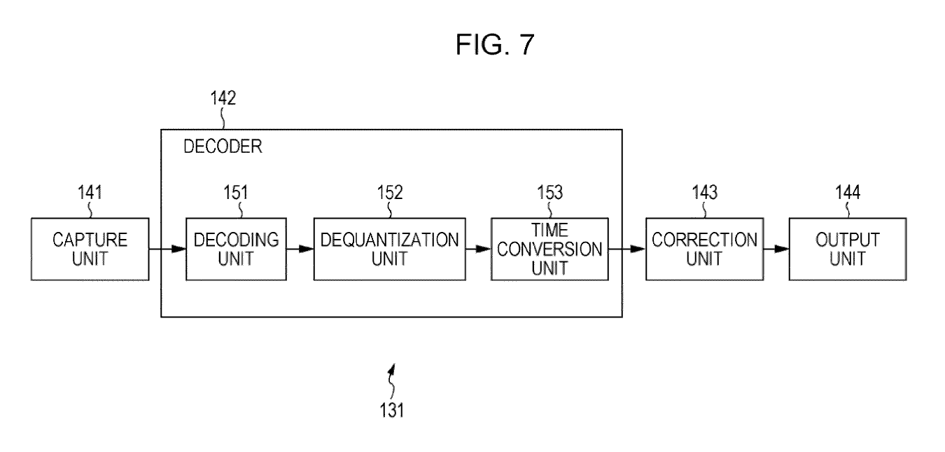

FIG. 7 is a block diagram showing an example structure of an audio playback apparatus according to an embodiment of the present invention. An audio playback apparatus 131 includes a capture unit 141, a decoder 142, a correction unit 143, and an output unit 144.

The capture unit 141 captures audio data of musical pieces from an optical disk such as a compact disc (CD) placed in the audio playback apparatus 131 or a device connected to the audio playback apparatus 131, and records the captured audio data. The audio data may be data encoded using an encoding method such as ATRAC or MP3. Further, the capture unit 141 supplies the recorded audio data to the decoder 142.

The decoder 142 receives and decodes audio data of a musical piece to be played back from the capture unit 141. The decoder 142 includes a decoding unit 151, a dequantization unit 152, and a time conversion unit 153.

The decoding unit 151 decodes the audio data received from the capture unit 141 to convert code strings forming the audio data into quantized information, and supplies the quantized information to the dequantization unit 152. The dequantization unit 152 dequantizes the quantized information supplied from the decoding unit 151 into frequency information, and supplies the frequency information to the time conversion unit 153. The time conversion unit 153 performs time conversion on the frequency information supplied from the dequantization unit 152 to convert the frequency information into audio data indicating the amplitudes of the musical piece at different times. Then, the time conversion unit 153 supplies the audio data obtained by time conversion to the correction unit 143 as decoded audio data.

The correction unit 143 performs band spreading on the audio data supplied from the time conversion unit 153, and supplies the band-spread audio data to the output unit 144. The output unit 144 includes, for example, speakers and plays back the musical piece on the basis of the audio data supplied from the correction unit 143.

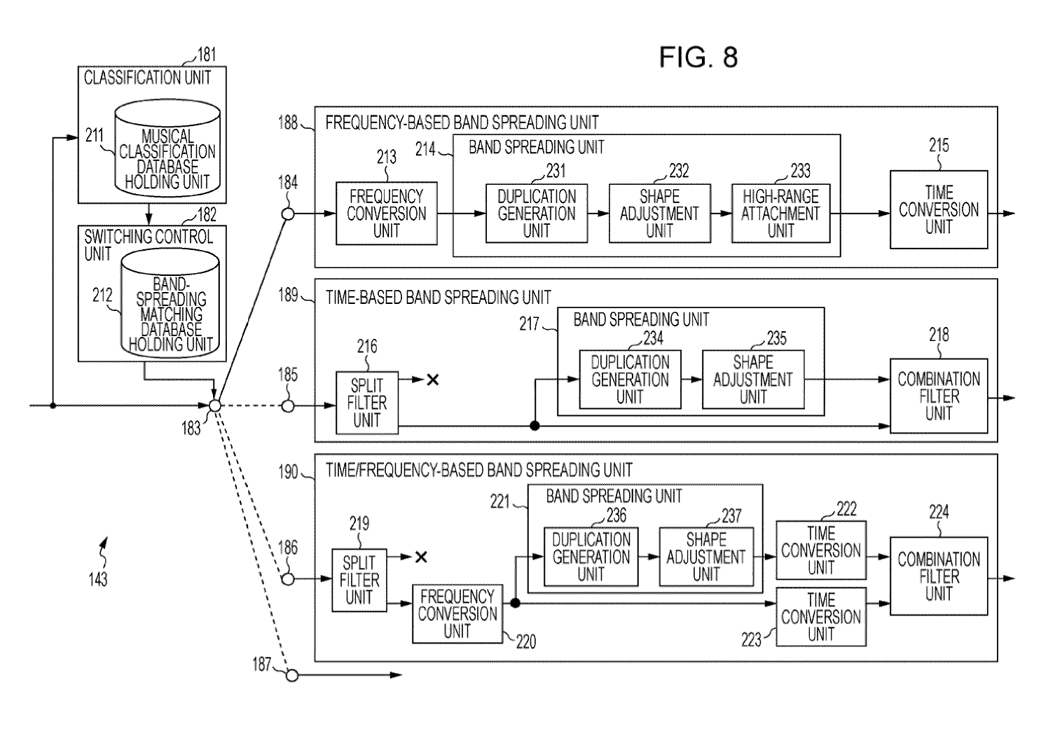

The correction unit 143 shown in FIG. 7 has a structure shown in, for example, FIG. 8. Specifically, the correction unit 143 includes a classification unit 181, a switching control unit 182, a switching unit 183, nodes 184 to 187, a frequency-based band spreading unit 188, a time-based band spreading unit 189, and a time/frequency-based band spreading unit 190. The audio data supplied from the time conversion unit 153 is supplied to the classification unit 181 and the switching unit 183.

The classification unit 181 performs, on the basis of the audio data supplied from the time conversion unit 153, classification on the musical piece based on the audio data. For example, the classification unit 181 performs 12-level sound analysis to extract a musical feature value indicating a feature of the musical piece from the audio data. Then, the classification unit 181 classifies the musical piece using the extracted musical feature value and a musical classification database held in a musical classification database holding unit 211. The musical classification database holding unit 211 is provided in the classification unit 181.

For example, the musical classification database holding unit 211 records a musical classification database including pieces of classification information and musical feature values associated with the pieces of classification information. The pieces of classification information indicate musical classes which represent types (categories) of musical pieces such as rock music, pop music, classical music, jazz music, and vocal music. The musical feature values included in the musical classification database are average musical feature values extracted from musical pieces belonging to the associated musical classes.

The classification unit 181 refers to the musical classification database recorded in the musical classification database holding unit 211, and supplies classification information associated with a musical feature value that is the closest to the musical feature value extracted from the audio data to the switching control unit 182.

The classification of musical pieces may not necessarily be based on categories. Alternatively, the classification of musical pieces may be based on the moods of musical pieces, such as happy and sad, or the tempos of musical pieces, such as fast and slow. Any kind of information indicating features of musical pieces may be used for the classification of musical pieces.

The switching control unit 182 selects a band spreading scheme on the basis of the classification information supplied from the classification unit 181, and controls the operation of the switching unit 183 so as to perform band spreading using the selected band spreading scheme.

The switching control unit 182 includes a band-spreading matching database holding unit 212, and the band-spreading matching database holding unit 212 records a band-spreading matching database. The band-spreading matching database includes classification information indicating musical classes, and information indicating combinations of the band spreading methods, the high-range-component generation methods, and the shape adjustment methods, which are associated with the classification information. The switching control unit 182 refers to the band-spreading matching database to select a band spreading scheme associated with the classification information supplied from the classification unit 181.

The switching unit 183 includes, for example, a switch. The switching unit 183 switches the output of the audio data from the time conversion unit 153 under control of the switching control unit 182. Specifically, the switching unit 183 is connected to one of the nodes 184 to 187 to output the audio data to the frequency-based band spreading unit 188, the time-based band spreading unit 189, the time/frequency-based band spreading unit 190, or the output unit 144.

The frequency-based band spreading unit 188 performs band spreading on the audio data supplied from the switching unit 183 via the node 184 using the frequency-based band spreading scheme. The frequency-based band spreading unit 188 includes a frequency conversion unit 213, a band spreading unit 214, and a time conversion unit 215.

The frequency conversion unit 213 performs frequency conversion on the audio data supplied from the switching unit 183 to produce frequency information, and supplies the frequency information to the band spreading unit 214.

The band spreading unit 214 generates band-spread frequency information using the frequency information supplied from the frequency conversion unit 213. The band spreading unit 214 includes a duplication generation unit 231, a shape adjustment unit 232, and a high-range attachment unit 233.

The duplication generation unit 231 generates pseudo high-range components to be added to the musical piece, more specifically, frequency information of high-frequency components, using the frequency information supplied from the frequency conversion unit 213 using a predetermined high-range-component generation method, and supplies the generated high-range components and the frequency information supplied from the frequency conversion unit 213 to the shape adjustment unit 232.

The shape adjustment unit 232 modifies the high-range components supplied from the duplication generation unit 231 using a predetermined shape adjustment method to adjust the shape of the high-range components, and supplies the shape-adjusted high-range components and the frequency information regarding the musical piece supplied from the duplication generation unit 231 to the high-range attachment unit 233. Upon receiving the frequency information and the high-range components from the shape adjustment unit 232, the high-range attachment unit 233 adds the high-range components to the frequency information and supplies resulting frequency information to the time conversion unit 215. The time conversion unit 215 performs time conversion to convert the frequency information supplied from the high-range attachment unit 233 into audio data, and supplies the resulting audio data to the output unit 144.

Further, the time-based band spreading unit 189 performs band spreading on the audio data supplied from the switching unit 183 via the node 185 using the time-based band spreading scheme. The time-based band spreading unit 189 includes a split filter unit 216, a band spreading unit 217, and a combination filter unit 218.

The split filter unit 216 splits the audio data supplied from the switching unit 183 into frequency bands using a split filter, and extracts audio data of low-range components of the musical piece, for example, components of 0 kHz to 10 kHz of the musical piece, from the audio data. The split filter unit 216 supplies the extracted audio data to the band spreading unit 217 and the combination filter unit 218.

The band spreading unit 217 generates pseudo high-range components to be added to the musical piece using the audio data supplied from the split filter unit 216. The band spreading unit 217 includes a duplication generation unit 234 and a shape adjustment unit 235.

The duplication generation unit 234 generates pseudo high-range components of the musical piece, more specifically, audio data of high-range components, using the audio data supplied from the split filter unit 216 using a predetermined high-range-component generation method, and supplies the generated high-range components to the shape adjustment unit 235. The shape adjustment unit 235 modifies the high-range components supplied from the duplication generation unit 234 using a predetermined shape adjustment method to adjust the shape of the high-range components, and supplies the shape-adjusted high-range components to the combination filter unit 218.

The combination filter unit 218 combines the frequency bands of the audio data supplied from the split filter unit 216 and the audio data of the high-range components supplied from the shape adjustment unit 235 using a combination filter, and supplies resulting audio data to the output unit 144.

Further, the time/frequency-based band spreading unit 190 performs band spreading on the audio data supplied from the switching unit 183 via the node 186 using the time/frequency-based band spreading scheme. The time/frequency-based band spreading unit 190 includes a split filter unit 219, a frequency conversion unit 220, a band spreading unit 221, time conversion units 222 and 223, and a combination filter unit 224.

The split filter unit 219 splits the audio data supplied from the switching unit 183 into frequency bands using a split filter to extract audio data of low-range components of the musical piece from the audio data, and supplies the extracted audio data to the frequency conversion unit 220. The frequency conversion unit 220 performs frequency conversion on the audio data of the low-range components supplied from the split filter unit 219 to produce frequency information, and supplies the frequency information to the band spreading unit 221 and the time conversion unit 223.

The band spreading unit 221 generates high-range components to be added to the musical piece using the frequency information supplied from the frequency conversion unit 220. The band spreading unit 221 includes a duplication generation unit 236 and a shape adjustment unit 237.

The duplication generation unit 236 generates pseudo high-range components to be added to the musical piece, more specifically, frequency information of high-frequency components, using the frequency information supplied from the frequency conversion unit 220 using a predetermined high-range-component generation method, and supplies the generated high-range components to the shape adjustment unit 237. The shape adjustment unit 237 modifies the high-range components supplied from the duplication generation unit 236 using a predetermined shape adjustment method to adjust the shape of the high-range components, and supplies the shape-adjusted high-range components to the time conversion unit 222.

The time conversion unit 222 performs time conversion to convert the frequency information supplied from the shape adjustment unit 237 into audio data, and supplies the audio data to the combination filter unit 224. Further, the time conversion unit 223 performs time conversion to convert the frequency information supplied from the frequency conversion unit 220 into audio data, and supplies the audio data to the combination filter unit 224. The combination filter unit 224 combines the frequency bands of the audio data supplied from the time conversion unit 222 and the audio data supplied from the time conversion unit 223 using a combination filter, and supplies resulting audio data to the output unit 144.

When the power of the audio playback apparatus 131 is turned on and a musical piece to be played back is specified by a user, the audio playback apparatus 131 performs a playback process of capturing and playing back audio data for playing back the musical piece specified by the user.

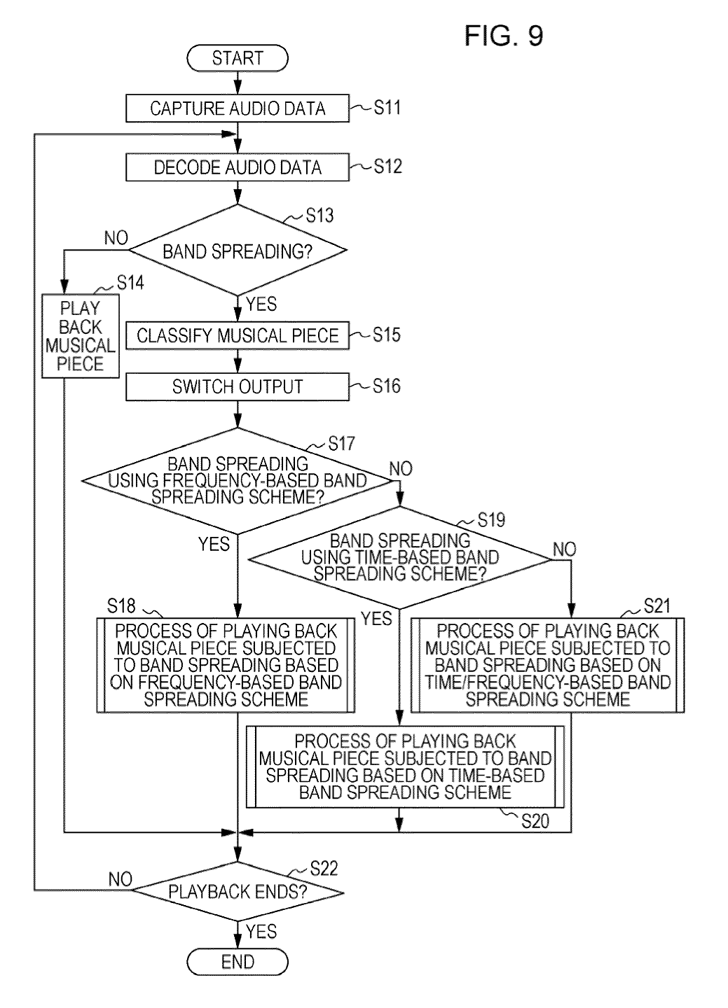

The playback process performed by the audio playback apparatus 131 will now be described with reference to a flowchart shown in FIG. 9.

In step S11, the capture unit 141 captures and records therein audio data of some musical pieces to be played back in accordance with an operation performed by a user. For example, the capture unit 141 captures audio data from an optical disk placed in the audio playback apparatus 131, a hard disk provided in the audio playback apparatus 131, a device connected to the audio playback apparatus 131, or the like. The audio data captured by the capture unit 141 may also be recorded in a non-volatile memory provided in the audio playback apparatus 131, such as a hard disk.

In step S12, the decoder 142 obtains the audio data of a musical piece specified by the user from the capture unit 141, and decodes the audio data.

Specifically, the decoding unit 151 obtains audio data from the capture unit 141, and decodes the audio data into quantized information. Then, the decoding unit 151 supplies the quantized information to the dequantization unit 152. The dequantization unit 152 dequantizes the quantized information supplied from the decoding unit 151 into frequency information, and supplies the frequency information to the time conversion unit 153. The time conversion unit 153 performs time conversion to convert the frequency information supplied from the dequantization unit 152, which indicates the powers of the respective frequencies of the musical piece, into audio data indicating the amplitudes of the musical piece at different times. This audio data is supplied as decoded audio data from the time conversion unit 153 to the classification unit 181 and the switching unit 183.

In step S13, the correction unit 143 determines whether or not band spreading is to be performed. For example, when a user performs an operation to instruct the audio playback apparatus 131 to perform band spreading, it is determined that band spreading is to be performed.

When the power of the audio playback apparatus 131 is turned off, the audio playback apparatus 131 may record therein information indicating whether or not the user has instructed the audio playback apparatus 131 to perform band spreading. Thus, next time the power of the audio playback apparatus 131 is turned on, the audio playback apparatus 131 may immediately determine whether or not band spreading is to be performed on the basis of the recorded information.

If it is determined in step S13 that band spreading is not to be performed, the correction unit 143 instructs the switching control unit 182 to output the audio data to the node 187. Then, the switching control unit 182 controls the operation of the switching unit 183 in accordance with the instruction of the correction unit 143 so that the switching unit 183 is connected to the node 187. Then, the switching unit 183 switches the output of the audio data to the node 187. Thereafter, the process proceeds to step S14.

In step S14, the output unit 144 plays back the musical piece. Specifically, the switching unit 183 supplies the audio data supplied from the time conversion unit 153 to the output unit 144 via the node 137. The output unit 144 plays back the musical piece on the basis of the audio data supplied from the switching unit 183. Therefore, the musical piece, which has not been subjected to band spreading, is played back. When the musical piece is played back in step S14, the process proceeds to step S22.

On the other hand, if it is determined in step S13 that band spreading is to be performed, in step S15, the classification unit 181 classifies the musical piece on the basis of the audio data of the musical piece supplied from the time conversion unit 153, and supplies a classification result to the switching control unit 182.

For example, in a case where the classification unit 181 is configured to classify a musical piece by performing 12-level sound analysis, the classification unit 181 divides audio data of one musical piece into a plurality of octave signals, performs a filtering process on each of the octave signals, and extracts 12 musical interval signals for each octave. Then, the classification unit 181 determines a musical feature value using the 12 musical interval signals obtained from the audio data. The musical feature value represents features of the musical piece, such as beat structure and chord progression.

The classification unit 181 further refers to the musical classification database in the musical classification database holding unit 211 to find classification information associated with a musical feature value that is the closest to (the most similar to) the musical feature value extracted from the audio data, and supplies the found classification information to the switching control unit 182 as a classification result of the musical piece. This classification information indicates a musical class into which the musical piece is classified.

In this manner, the entire audio data of one musical piece is used to classify this musical piece. This provides more reliable classification than that in a case where only a portion of audio data is used to classify a musical section corresponding to this portion.

Instead of classifying a musical piece, the classification unit 181 may obtain classification information from a device connected to the audio playback apparatus 131 via a communication network such as the Internet or may obtain classification information from an optical disk placed in the audio playback apparatus 131 through the decoder 142 and the capture unit 141. For example, in an optical disk that supports the CD-Text standard, classification information is recorded in a lead-in area of the optical disk.

Alternatively, when the capture unit 141 captures audio data of a musical piece, the musical piece may be classified and a classification result may be recorded. By recording the classification result of the musical piece in advance, the playback of the musical piece can be more quickly started.

In step S16, the switching unit 183 switches the output of the audio data supplied from the time conversion unit 153 under control of the switching control unit 182.

Specifically, the switching control unit 182 refers to the band-spreading matching database in the band-spreading matching database holding unit 212 to select a band spreading method associated with the classification information supplied from the classification unit 181. Then, the switching control unit 182 controls the switching unit 183 in accordance with the selected band spreading method so that the audio data can be supplied to one of the nodes 184 to 186. For example, when the frequency-based band spreading scheme is selected as a band spreading method, the switching control unit 182 controls the switching unit 183 to be connected to the node 184 so that band spreading can be performed using the frequency-based band spreading scheme.

In step S17, the switching control unit 182 determines whether or not band spreading is to be performed using the frequency-based band spreading scheme. For example, when the switching unit 183 is connected to the node 184 and the audio data is supplied from the switching unit 183 to the frequency-based band spreading unit 188, it is determined that band spreading is to be performed using the frequency-based band spreading scheme.

If it is determined in step S17 that band spreading is to be performed using the frequency-based band spreading scheme, in step S18, the audio playback apparatus 131 performs a process of playing back the musical piece which has been subjected to a band spreading process based on the frequency-based band spreading scheme. In the process of playing back a musical piece subjected to a band spreading process based on the frequency-based band spreading scheme, band spreading is performed on the musical piece using the frequency-based band spreading scheme, and the musical piece is played back. That is, band spreading in the frequency domain is performed. The process of playing back a musical piece subjected to a band spreading process based on the frequency-based band spreading scheme will be described in detail below.

After the process of playing back the musical piece subjected to the band spreading process based on the frequency-based band spreading scheme is performed, the process proceeds to step S22.

On the other hand, if it is determined in step S17 that band spreading is not to be performed using the frequency-based band spreading scheme, in step S19, the switching control unit 182 determines whether or not band spreading is to be performed using the time-based band spreading scheme. For example, when the switching unit 183 is connected to the node 185 and the audio data is supplied from the switching unit 183 to the time-based band spreading unit 189, it is determined that band spreading is to be performed using the time-based band spreading scheme.

If it is determined in step S19 that band spreading is to be performed using the time-based band spreading scheme, in step S20, the audio playback apparatus 131 performs a process of playing back the musical piece which has been subjected to a band spreading process based on the time-based band spreading scheme. In the process of playing back a musical piece subjected to a band spreading process based on the time-based band spreading scheme, band spreading is performed on the musical piece using the time-based band spreading scheme, and the musical piece is played back. That is, band spreading in the time domain is performed. The process of playing back a musical piece subjected to a band spreading process based on the time-based band spreading scheme will be described in detail below.

After the process of playing back the musical piece subjected to the band spreading process based on the time-based band spreading scheme is performed, the process proceeds to step S22.

If it is determined in step S19 that band spreading is not to be performed using the time-based band spreading scheme, in step S21, the audio playback apparatus 131 performs a process of playing back the musical piece which has been subjected to a band spreading process based on the time/frequency-based band spreading scheme. In the process of playing back a musical piece subjected to a band spreading process based on the time/frequency-based band spreading scheme, band spreading is performed on the musical piece using the time/frequency-based band spreading scheme, and the musical piece is played back. That is, band spreading in both the time domain and the frequency domain is performed. The process of playing back a musical piece subjected to a band spreading process based on the time/frequency-based band spreading scheme will be described in detail below.

After the process of playing back the musical piece subjected to the band spreading process based on the time/frequency-based band spreading scheme is performed, the process proceeds to step S22.

When one musical piece is played back in step S14, S18, S20, or S21, then in step S22, the audio playback apparatus 131 determines whether or not the playback of the musical pieces is to be terminated. For example, when the playback of all the musical pieces specified by the user has been completed, it is determined that the playback is to be terminated.

If it is determined in step S22 that the playback is not to be terminated, the process returns to step S12 and the process described above is repeated to play back a next musical piece.

On the other hand, if it is determined in step S22 that the playback is to be terminated, the respective sections of the audio playback apparatus 131 terminate the processes that are in progress. Then, the playback process ends.

In this manner, the audio playback apparatus 131 classifies musical pieces, and changes a band spreading method in accordance with a classification result. Then, the audio playback apparatus 131 performs band spreading on audio data for one musical piece using an identical band spreading method.

In this manner, a band spreading method is changed in accordance with a classification result of a musical piece. Therefore, band spreading can be performed using a band spreading method that is the most suitable for the musical class of the musical piece. In other words, a band spreading method that is the most effective for a musical piece to be played back to improve the sound quality can be used to perform band spreading on audio data. This can more reliably improve the quality of musical pieces (audio) than in the related art.

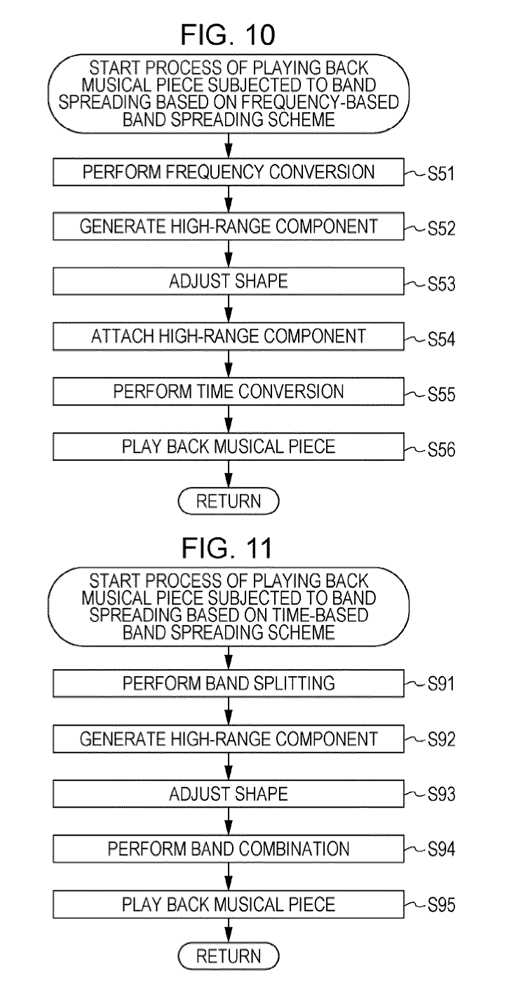

Next, a process of playing back a musical piece subjected to a band spreading process based on the frequency-based band spreading scheme, which corresponds to the processing of step S18 shown in FIG. 9, will be described with reference to a flowchart shown in FIG. 10.

In step S51, the frequency conversion unit 213 performs frequency conversion on the audio data supplied from the switching unit 183 to produce frequency information, and supplies the frequency information to the duplication generation unit 231. The frequency conversion unit 213 performs frequency conversion, for example, orthogonal transform such as discrete Fourier transform or modified discrete cosine transform. Accordingly, frequency information indicating the magnitudes of respective frequency components contained in the musical piece, that is, the powers of the respective frequencies, can be obtained.

In step S52, the duplication generation unit 231 generates pseudo high-range components to be added to the musical piece, for example, components in a specific frequency band such as a range of 10 kHz to 20 kHz, using the frequency information supplied from the frequency conversion unit 213 using a predetermined high-range-component generation method such as the fold-back scheme. More specifically, the high-range components (high-frequency components) are frequency information indicating the powers of the respective frequencies in a specific frequency band, that is, frequency information regarding audio at specific frequencies, which is generated using components in some or all the frequency bands included in the frequency information regarding the musical piece.

After generating high-range components, the duplication generation unit 231 supplies the generated high-range components and the frequency information supplied from the frequency conversion unit 213 to the shape adjustment unit 232.

In step S53, the shape adjustment unit 232 adjusts the shape of the high-range components supplied from the duplication generation unit 231 using a predetermined shape adjustment method such as the extrapolation scheme. Specifically, the shape adjustment unit 232 increases or decreases the powers of the respective frequencies of the high-range components to adjust the shape of the high-range components. Then, the shape adjustment unit 232 supplies the shape-adjusted high-range components and the frequency information regarding the musical piece supplied from the duplication generation unit 231 to the high-range attachment unit 233.

In step S54, upon receiving the frequency information and the high-range components from the shape adjustment unit 232, the high-range attachment unit 233 attaches the high-range components to the frequency information, and supplies resulting frequency information to the time conversion unit 215. Specifically, the powers of frequencies in a high-frequency range, which are not included in the frequency information, are added to the frequency information regarding the musical piece which includes the powers of frequencies in a low-frequency range, and frequency information indicating the powers of the respective frequencies in the range from the low-frequency range to the high-frequency range is generated.

In step S55, the time conversion unit 215 performs time conversion to convert the frequency information supplied from the high-range attachment unit 233 into audio data, and supplies the obtained audio data to the output unit 144. The time conversion unit 215 performs time conversion such as, for example, inverse discrete Fourier transform or inverse modified discrete cosine transform, to convert the frequency information into audio data having a time waveform, that is, audio data indicating the amplitudes of the musical piece at different times.

In step S56, the output unit 144 plays back the musical piece on the basis of the audio data supplied from the time conversion unit 215. When the musical piece subjected to band spreading using the frequency-based band spreading scheme is played back in the manner described above, the process of playing back a musical piece subjected to a band spreading process based on the frequency-based band spreading scheme ends. Then, the process proceeds to step S22 shown in FIG. 9.

Accordingly, the audio playback apparatus 131 performs band spreading on a musical piece (audio data) in the frequency domain, and plays back a resulting musical piece. The band spreading in the frequency domain in the manner described above allows the higher-accuracy estimation of high-range components originally contained in the musical piece, and allows more reliable improvement in quality of the musical piece.

Next, a process of playing back a musical piece subjected to a band spreading process based on the time-based band spreading scheme, which corresponds to the processing of step S20 shown in FIG. 9, will be described with reference to a flowchart shown in FIG. 11.

In step S91, the split filter unit 216 splits the audio data supplied from the switching unit 183 into frequency bands using a split filter, and extracts low-range components of the musical piece from the audio data. The split filter unit 216 supplies audio data including the extracted low-range components to the duplication generation unit 234 and the combination filter unit 218.

In step S92, the duplication generation unit 234 generates high-range components to be added to the musical piece using the audio data supplied from the split filter unit 216 using a predetermined high-range-component generation method such as the fold-back scheme, and supplies the high-range components to the shape adjustment unit 235.

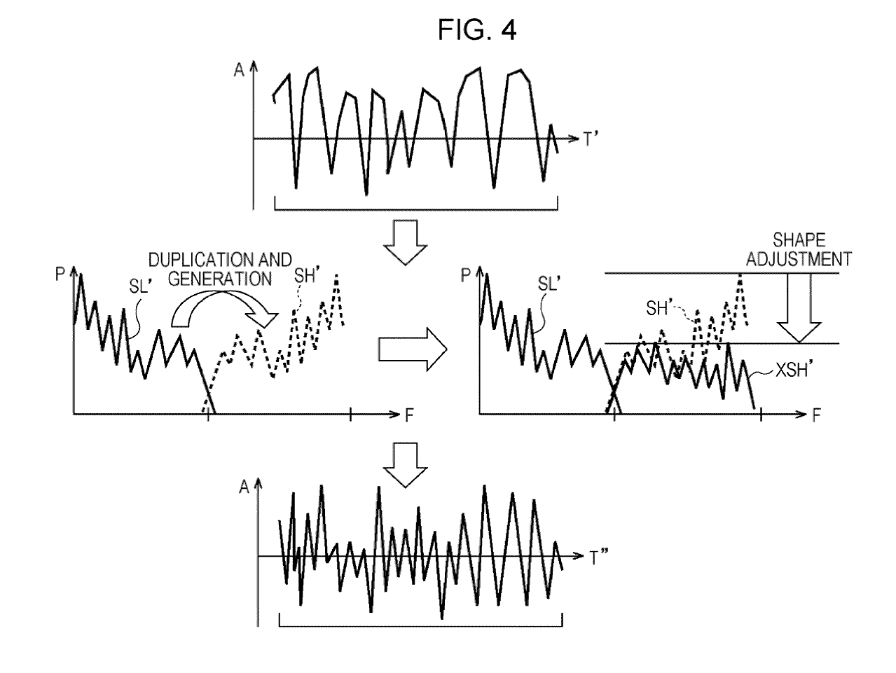

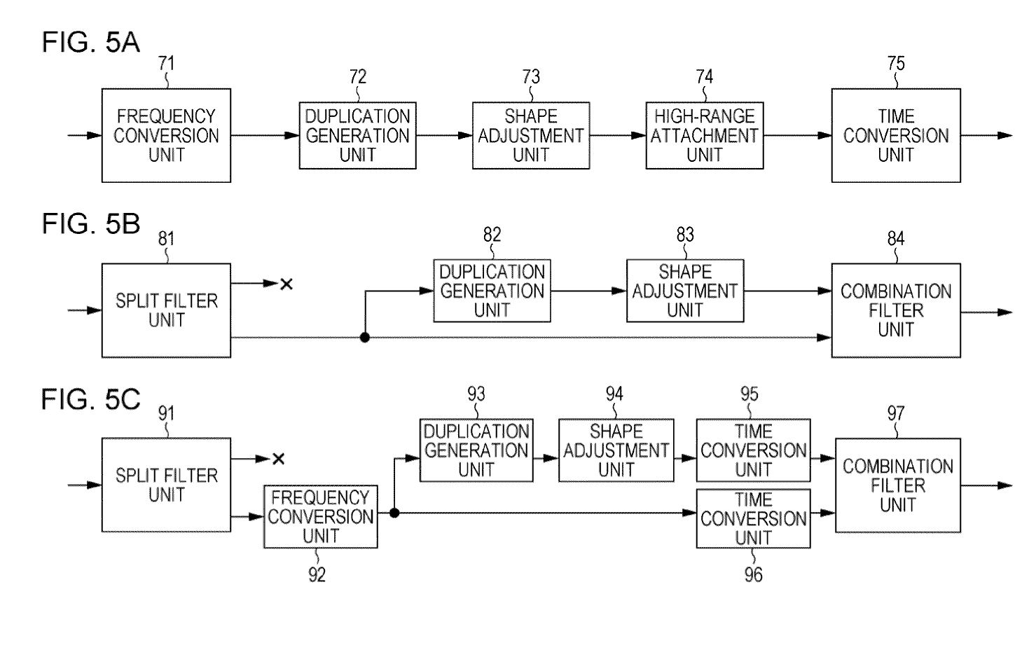

Specifically, for example, the duplication generation unit 234 performs frequency modulation on audio data having a time waveform to generate, as high-range components, audio data of audio including components in a specific frequency band. As a specific example of frequency modulation, as shown in FIG. 4, low-range components obtained by a split filter may be simply used as high-range components which would have been obtained by the same split filter. Other various methods may also be selected as desired. Here, the high-range components generated by the duplication generation unit 234 may be audio data indicating the amplitudes, at different times, of audio to be added to the musical piece.

Even when high-range components are generated using an identical high-range-component generation method, for example, the duplication generation unit 231 generates high-range components (frequency information regarding high-frequency components) using frequency information while the duplication generation unit 234 generates high-range components (audio data of high-frequency components) using audio data. That is the types of data to be handled differ depending on the band spreading scheme.

In step S93, the shape adjustment unit 235 adjusts the shape of the high-range components supplied from the duplication generation unit 234 using a predetermined shape adjustment method such as the learning scheme, and supplies the shape-adjusted high-range components to the combination filter unit 218. Specifically, the shape adjustment unit 235 appropriately changes the amplitudes, at different times, of audio of audio data serving as the supplied high-range components to adjust the shape of the high-range components. More specifically, for example, the shape (frequency characteristic) of the high-range components is adjusted by performing a convolution between a filter coefficient of a filter having a predetermined shape (frequency characteristic), such as a finite impulse response (FIR) filter or an infinite impulse response (IIR) filter, and a time signal of the high-range components.

In step S94, the combination filter unit 218 combines the frequency bands of the audio data supplied from the split filter unit 216 and the audio data supplied as the high-range components from the shape adjustment unit 235 using a combination filter, and supplies resulting audio data to the output unit 144. That is, the combination filter unit 218 adds the audio data of the high-range components to the audio data of the low-range components to generate audio data of the musical piece which contains individual frequency components in a range from low frequencies to high frequencies.

In step S95, the output unit 144 plays back the musical piece on the basis of the audio data supplied from the combination filter unit 218. When the musical piece subjected to the band spreading using the time-based band spreading scheme is played back in the manner described above, the process of playing back a musical piece subjected to a band spreading process based on the time-based band spreading scheme ends. Then, the process proceeds to step S22 shown in FIG. 9.

Accordingly, the audio playback apparatus 131 performs band spreading on a musical piece (audio data) in the time domain, and plays back a resulting musical piece. The band spreading in the time domain in the manner described above allows the generation of high-range components whose time change matches the time change of the original low-range components, and allows more reliable improvement in quality of the musical piece.

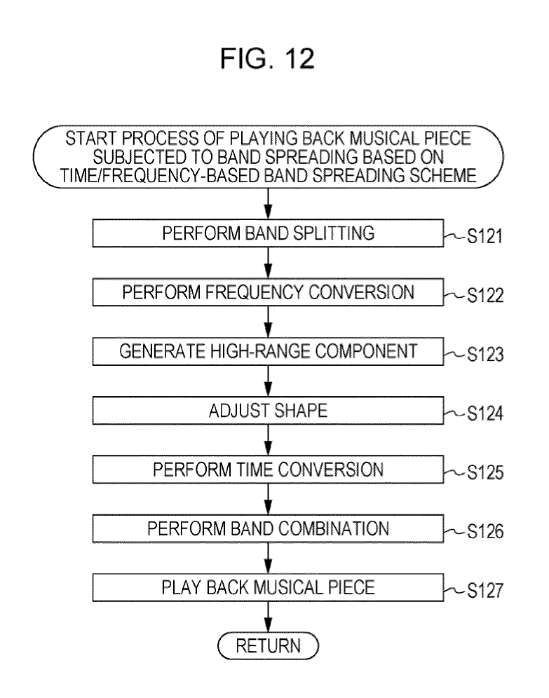

Furthermore, a process of playing back a musical piece subjected to a band spreading process based on the time/frequency-based band spreading scheme, which corresponds to the processing of step S21 shown in FIG. 9, will be described with reference to a flowchart shown in FIG. 12.

In step S121, the split filter unit 219 splits the audio data supplied from the switching unit 183 into frequency bands using a split filter, and extracts low-range components of the musical piece from the audio data. The split filter unit 219 supplies audio data including the extracted low-range components to the frequency conversion unit 220.

In step S122, the frequency conversion unit 220 performs frequency conversion on the audio data supplied from the split filter unit 219 to produce frequency information, and supplies the frequency information to the duplication generation unit 236 and the time conversion unit 223. The frequency conversion unit 220 performs frequency conversion, for example, orthogonal transform such as discrete Fourier transform or modified discrete cosine transform. Accordingly, frequency information indicating the powers of the respective frequencies included in the musical piece can be obtained.

In step S123, the duplication generation unit 236 generates high-range components of the musical piece, for example, components in a specific frequency band such as a range of 10 kHz to 20 kHz, using the frequency information supplied from the frequency conversion unit 220 using a predetermined high-range-component generation method such as the fold-back scheme. More specifically, the high-range components (high-frequency components) are frequency information indicating the powers of the respective frequencies in a specific frequency band, which is generated using components in some or all the frequency bands included in the frequency information regarding the musical piece.

In step S124, the shape adjustment unit 237 adjusts the shape of the high-range components-supplied from the duplication generation unit 235 using a predetermined shape adjustment method such as the extrapolation scheme, and supplies the shape-adjusted high-range components to the time conversion unit 222. Specifically, the shape adjustment unit 237 increases or decreases the powers of the respective frequencies of the high-range components to adjust the shape of the high-range components.

In step S125, the time conversion units 222 and 223 perform time conversion on the high-range components supplied from the shape adjustment unit 237 and the frequency information supplied from the frequency conversion unit 220, respectively, to produce audio data, and supply the audio data to the combination filter unit 224. The time conversion units 222 and 223 perform time conversion such as, for example, inverse discrete Fourier transform or inverse modified discrete cosine transform, to convert the frequency information into audio data having a time waveform, that is, audio data indicating the amplitudes of audio at different times.

In step S126, the combination filter unit 224 combines the frequency bands of the audio data supplied as high-range components from the time conversion unit 222 and the audio data supplied from the time conversion unit 223 using a combination filter, and supplies resulting audio data to the output unit 144. Therefore, audio data of the musical piece which contains individual components in a range from low frequencies to high frequencies can be obtained.

In step S127, the output unit 144 plays back the musical piece on the basis of the audio data supplied from the combination filter unit 224. When the musical piece subjected to the band spreading using the time/frequency-based band spreading scheme is played back in the manner described above, the process of playing back a musical piece subjected to a band spreading process based on the time/frequency-based band spreading scheme ends. Then, the process proceeds to step S22 shown in FIG. 9.

Accordingly, the audio playback apparatus 131 performs a band spreading process on audio data of a musical piece in both the time domain and the frequency domain to play back the band-spread musical piece. The band spreading in both the time domain and the frequency domain in the manner described above allows the generation of high-range components having features of both the time-based band spreading scheme and the frequency-based band spreading scheme, and allows improvement in quality of the musical piece.

Further, audio data is converted into frequency information after band splitting is performed. Thus, only low-range components necessary for processing can be targeted for frequency conversion. This can reduce the amount of processing involved in frequency conversion and can provide more efficient and rapid generation of high-range components. Furthermore, band spreading using the time/frequency-based band spreading scheme can reduce the amount of processing involved in frequency conversion, thus ensuring that high-range components can be generated with a smaller hardware configuration.

The switching control unit 182 may refer to the band-spreading matching database to determine a high-range-component generation method on the basis of classification information, and may cause the duplication generation unit 231, 234, or 236 to generate high-range components using the determined high-range-component generation method. Alternatively, a high-range-component generation method may be changed in accordance with an instruction given from a user.

Similarly, the switching control unit 182 may refer to the band-spreading matching database to determine a shape adjustment method on the basis of classification information, and may cause the shape adjustment unit 232, 235, or 237 to adjust the shape using the determined shape adjustment method. Alternatively, a shape adjustment method may be changed in accordance with an instruction given from a user.

Furthermore, the output of audio data from the switching unit 183 may be switched in accordance with an instruction given from a user. That is, which of the nodes 184 to 186 the switching unit 183 is connected to may be changed in accordance with an instruction given from a user.

In the following description, by way of example, only a band spreading method is changed in accordance with a classification result of a musical piece. In addition to a band spreading method, a high-range-component generation method and a shape adjustment method may also be changed in accordance with a musical class of a musical piece.

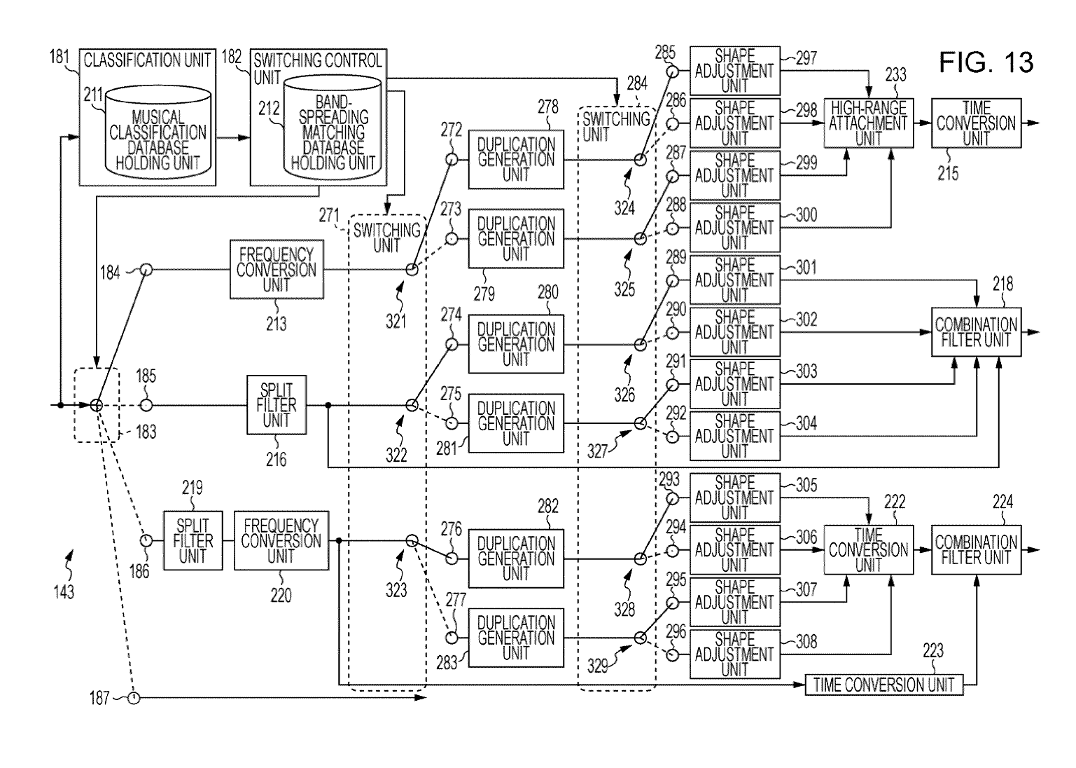

In this case, the correction unit 143 may have a structure shown in, for example, FIG. 13. In FIG. 13, portions corresponding to those shown in FIG. 8 are assigned the same reference numerals and the description thereof is omitted, if not necessary.

In the correction unit 143 shown in FIG. 13, the nodes 184, 185, and 186 are connected to the frequency conversion unit 213, the split filter unit 216, and the split filter unit 219, respectively, and the split filter unit 219 is connected to the frequency conversion unit 220.

Further, the frequency conversion unit 213, the split filter unit 216, and the frequency conversion unit 220 are connected to nodes 272 to 277 via a switching unit 271.

The switching unit 271 is provided with switches 321 to 323. The switch 321 is adapted to switch the output of the frequency information supplied from the frequency conversion unit 213 to the node 272 or 273. The switch 322 is adapted to switch the output of the audio data supplied from the split filter unit 216 to the node 274 or 275. The switch 323 is adapted to switch the output of the frequency information supplied from the frequency conversion unit 220 to the node 276 or 277. The switching unit 271 switches the connection of the switches 321 to 323 under control of the switching control unit 182.

The nodes 272 to 277 are connected to duplication generation units 278 to 283, respectively.

The duplication generation units 278, 280, and 282 generate pseudo high-range components to be added to the musical piece using the fold-back scheme using the frequency information supplied from the frequency conversion unit 213, the audio data supplied from the split filter unit 216, and the frequency information supplied from the frequency conversion unit 220, respectively.

The duplication generation units 279, 281, and 283 generate pseudo high-range components to be added to the musical piece using the translating scheme using the frequency information supplied from the frequency conversion unit 213, the audio data supplied from the split filter unit 216, and the frequency information supplied from the frequency conversion unit 220, respectively.

The high-range components generated by the duplication generation units 278 to 283 are supplied to nodes 285 to 296 via a switching unit 284. The switching unit 284 is provided with switches 324 to 329.

The switch 324 is adapted to switch the output of the high-range components supplied from the duplication generation unit 278 to the node 285 or 286. The switch 325 is adapted to switch the output of the high-range components supplied from the duplication generation unit 279 to the node 287 or 288.

The switch 326 is adapted to switch the output of the high-range components supplied from the duplication generation unit 280 to the node 289 or 290. The switch 327 is adapted to switch the output of the high-range components supplied from the duplication generation unit 281 to the node 291 or 292. The switch 328 is adapted to switch the output of the high-range components supplied from the duplication generation unit 282 to the node 293 or 294. The switch 329 is adapted to switch the output of the high-range components supplied from the duplication generation unit 283 to the node 295 or 296.

The switching unit 284 switches the connection of the switches 324 to 329 under control of the switching control unit 182.

The nodes 285 to 296 are further connected to shape adjustment units 297 to 308, respectively.

The shape adjustment units 297, 299, 301, 303, 305, and 307 adjust the shape of the high-range components supplied from the duplication generation units 278, 279, 280, 281, 282, and 283, respectively, using the extrapolation scheme.

The shape adjustment units 298, 300, 302, 304, 306, and 308 adjust the shape of the high-range components supplied from the duplication generation units 278, 279, 280, 281, 282, and 283, respectively, using the learning scheme.

The high-range components whose shape has been adjusted by the shape adjustment units 297 to 300 are supplied to the high-range attachment unit 233. The high-range components whose shape has been adjusted by the shape adjustment units 301 to 304 are supplied to the combination filter unit 218. The high-range components whose shape has been adjusted by the shape adjustment units 305 to 308 are supplied to the time conversion unit 222.

In the correction unit 143 shown in FIG. 13, therefore, the switching units 183, 271, and 284 switch the outputs of data depending on which band spreading method, high-range-component generation method, and shape adjustment method are used in combination.

In the correction unit 143 shown in FIG. 13, a section including the frequency conversion unit 213, the duplication generation units 278 and 279, the shape adjustment units 297 to 300, the high-range attachment unit 233, and the time conversion unit 215 corresponds to the frequency-based band spreading unit 188 shown in FIG. 8.

Similarly, in the correction unit 143 shown in FIG. 13, a section including the split filter unit 216, the duplication generation units 280 and 281, the shape adjustment units 301 to 304, and the combination filter unit 218 corresponds to the time-based band spreading unit 189 shown in FIG. 8. In the correction unit 143 shown in FIG. 13, further, a section including the split filter unit 219, the frequency conversion unit 220, the duplication generation units 282 and 283, the shape adjustment units 305 to 308, the time conversion units 222 and 223, and the combination filter unit 224 corresponds to the time/frequency-based band spreading unit 190 shown in FIG. 8.

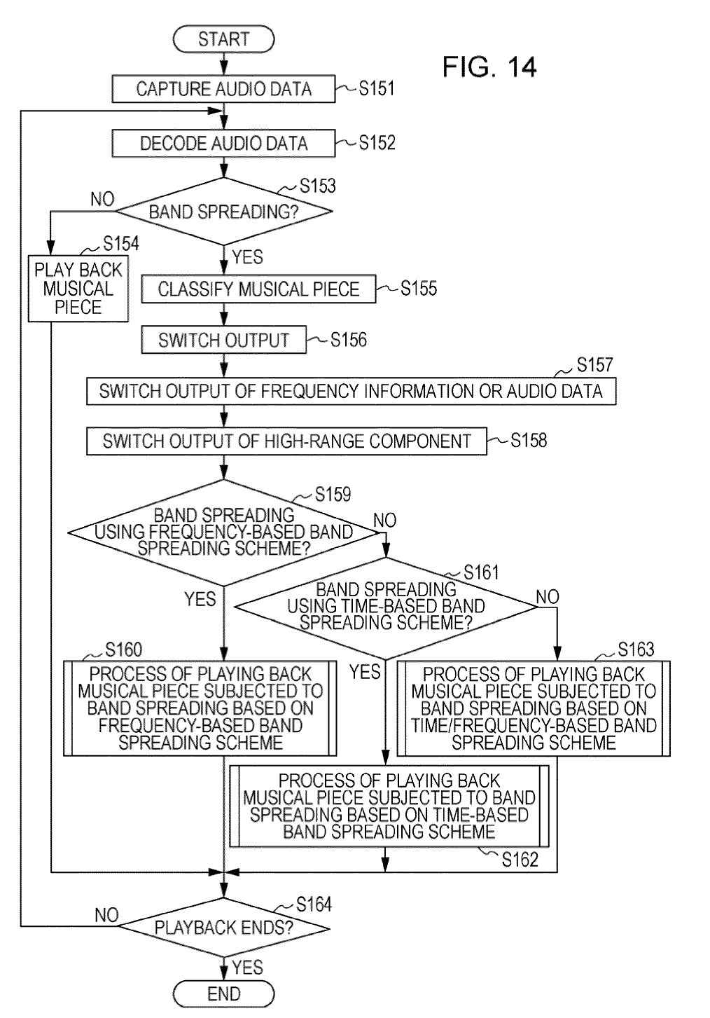

Next, a playback process performed by an audio playback apparatus that includes the correction unit 143 having the structure shown in FIG. 13 will be described with reference to a flowchart shown in FIG. 14. In FIG. 14, the processing of steps S151 to S155 is similar to that of steps S11 to S15 shown in FIG. 9, and the description thereof is omitted.

In step S155, the classification unit 181 classifies the musical piece, and supplies classification information regarding the musical piece to the switching control unit 182. Then, in step S156, the switching unit 183 switches the output of the audio data supplied from the time conversion unit 153 under control of the switching control unit 182.

Specifically, the switching control unit 182 refers to the band-spreading matching database in the band-spreading matching database holding unit 212 to select a band spreading scheme, a high-range-component generation method, and a shape adjustment method, which are associated with the classification information supplied from the classification unit 181.

Then, the switching control unit 182 controls the switching unit 183 in accordance with the selected band spreading scheme so that the audio data can be supplied to one of the nodes 184 to 186. Therefore, the audio data supplied from the switching unit 183 is supplied to the frequency conversion unit 213 via the node 184 when the frequency-based band spreading scheme is selected, to the split filter unit 216 via the node 185 when the time-based band spreading scheme is selected, and to the split filter unit 219 via the node 186 when the time/frequency-based band spreading scheme is selected.

In step S157, the switching unit 271 switches the output of the frequency information or audio data under control of the switching control unit 182. Specifically, the switching control unit 182 controls the operation of the switching unit 271 in accordance with the band spreading scheme and high-range-component generation method selected in the processing of step S156.

For example, when the frequency-based band spreading scheme and the fold-back scheme are selected, the switching control unit 182 causes the switch 321 in the switching unit 271 to be connected to the node 272. When the frequency-based band spreading scheme and the translating scheme are selected, the switching control unit 182 causes the switch 321 in the switching unit 271 to be connected to the node 273.

When the time-based band spreading scheme and the fold-back scheme are selected, the switching control unit 182 causes the switch 322 in the switching unit 271 to be connected to the node 274. When the time-based band spreading scheme and the translating scheme are selected, the switching control unit 182 causes the switch 322 in the switching unit 271 to be connected to the node 275. When the time/frequency-based band spreading scheme and the fold-back scheme are selected, the switching control unit 182 causes the switch 323 in the switching unit 271 to be connected to the node 276. When the time/frequency-based band spreading scheme and the translating scheme are selected, the switching control unit 182 causes the switch 323 in the switching unit 271 to be connected to the node 277.

In step S158, the switching unit 284 switches the output of the high-range components under control of the switching control unit 182. Specifically, the switching control unit 182 controls the operation of the switching unit 284 in accordance with the band spreading scheme, high-range-component generation method, and shape adjustment method selected in the processing of step S156.

For example, in a case where the frequency-based band spreading scheme and the fold-back scheme are selected, the switching control unit 182 causes the switch 324 in the switching unit 284 to be connected to the node 285 when the extrapolation scheme is selected, and causes the switch 324 in the switching unit 284 to be connected to the node 286 when the learning scheme is selected. In a case where the frequency-based band spreading scheme and the translating scheme are selected, the switching control unit 182 causes the switch 325 in the switching unit 284 to be connected to the node 287 when the extrapolation scheme is selected, and causes the switch 325 in the switching unit 284 to be connected to the node 288 when the learning scheme is selected.

Similarly, in a case where the time-based band spreading scheme and the fold-back scheme are selected, the switching control unit 182 causes the switch 326 in the switching unit 284 to be connected to the node 289 when the extrapolation scheme is selected, and causes the switch 326 in the switching unit 284 to be connected to the node 290 when the learning scheme is selected. In a case where the time-based band spreading scheme and the translating scheme are selected, the switching control unit 182 causes the switch 327 in the switching unit 284 to be connected to the node 291 when the extrapolation scheme is selected, and causes the switch 327 in the switching unit 284 to be connected to the node 292 when the learning scheme is selected.

In a case where the time/frequency-based band spreading scheme and the fold-back scheme are selected, the switching control unit 182 causes the switch 328 in the switching unit 284 to be connected to the node 293 when the extrapolation scheme is selected, and causes the switch 328 in the switching unit 284 to be connected to the node 294 when the learning scheme is selected. In a case where the time/frequency-based band spreading scheme and the translating scheme are selected, the switching control unit 182 causes the switch 329 in the switching unit 284 to be connected to the node 295 when the extrapolation scheme is selected, and causes the switch 329 in the switching unit 284 to be connected to the node 296 when the learning scheme is selected.

In this way, the switching control unit 182 causes the switching unit 183 to switch the output of the audio data so that band spreading can be performed using the specified band spreading method. The switching control unit 182 further causes the switching unit 271 to switch the output of frequency information or audio data so that high-range components can be generated using the specified high-range-component generation method. Further, the switching control unit 182 also causes the switching unit 284 to switch the output of the high-range components so that the shape of the high-range components can be adjusted using the specified shape adjustment method.

When the operations of the switching units 183, 271, and 284 are controlled in the manner described above, then the processing of steps S159 to S164 is performed. Then, the playback process ends. The processing of steps S159 to S164 is similar to that of steps S17 to S22 shown in FIG. 9, and the description thereof is omitted.

In steps S160, S162, and S163, processes similar to the process of playing back a musical piece subjected to a band spreading process based on the frequency-based band spreading scheme, the process of playing back a musical piece subjected to a band spreading process based on the time-based band spreading scheme, and the process of playing back a musical piece subjected to a band spreading process based on the time/frequency-based band spreading scheme, which have been described with reference to FIGS. 10 to 12, respectively.

Note that the process for generating high-range components is performed by a duplication generation unit among the duplication generation units 278 to 283 to which the frequency information or audio data has been supplied from the switching unit 271. Similarly, the process for adjusting the shape of the high-range components is performed by a shape adjustment unit among the shape adjustment units 297 to 308 to which the high-range components have been supplied from the switching unit 284.

For example, it is assumed that, in step S156, the switching control unit 182 selects the frequency-based band spreading scheme, the fold-back scheme, and the extrapolation scheme. In this case, in the process of playing back a musical piece subjected to a band spreading process based on the frequency-based band spreading scheme in step S160, the duplication generation unit 278 generates high-range components and the shape adjustment unit 297 adjusts the shape of the high-range components.

Specifically, in processing corresponding to the processing of step 351 shown in FIG. 10, the frequency conversion unit 213 converts the audio data into frequency information, and the frequency information is supplied to the duplication generation unit 278 via the switch 321 and the node 272. Then, in processing corresponding to the processing of step S52, the duplication generation unit 278 generates high-range components, and the high-range components and the frequency information are supplied to the shape adjustment unit 297 via the switch 324 and the node 285. In processing corresponding to the processing of step S53, the shape adjustment unit 297 adjusts the shape of the high-range components.

Thereafter, the shape-adjusted high-range component and the frequency information are supplied from the shape adjustment unit 297 to the high-range attachment unit 233. In processing corresponding to the processing of steps S54 and S55, the high-range attachment unit 233 attaches the high-range components to the frequency information, and the time conversion unit 215 converts resulting frequency information into audio data. Further, in processing corresponding to the processing of step S56, the output unit 144 plays back the musical piece.

Alternatively, for example, it is assumed that, in step S156, the switching control unit 182 selects the time-based band spreading scheme, the fold-back scheme, and the extrapolation scheme. In this case, in the process of playing back a musical piece subjected to a band spreading process based on the time-based band spreading scheme in step S162, the duplication generation unit 280 generates high-range components and the shape adjustment unit 301 adjusts the shape of the high-range components.

Specifically, the audio data supplied from the switching unit 183 is supplied to the split filter unit 216 and is subjected to band splitting using the split filter unit 216. Resulting audio data is supplied to the combination filter unit 218 and is also supplied to the duplication generation unit 280 via the switch 322 and the node 274. Then, the duplication generation unit 280 generates high-range components using the fold-back scheme using the audio data supplied from the split filter unit 216, and supplies the generated high-range components to the shape adjustment unit 301 via the switch 326 and the node 289.

The shape adjustment unit 301 adjusts the shape of the high-range components supplied from the duplication generation unit 280 using the extrapolation scheme, and supplies resulting high-range components to the combination filter unit 218. The combination filter unit 218 combines the frequency bands of the high-range components supplied from the shape adjustment unit 301 and the audio data supplied from the split filter unit 216, and supplies resulting audio data to the output unit 144.

Alternatively, for example, it is assumed that, in step S156, the switching control unit 182 selects the time/frequency-based band spreading scheme, the fold-back scheme, and the extrapolation scheme. In this case, in the process of playing back a musical piece subjected to a band spreading process based on the time/frequency-based band spreading scheme in step S163, the duplication generation unit 282 generates high-range components and the shape adjustment unit 305 adjusts the shape of the high-range components.

Specifically, the audio data supplied from the switching unit 183 is supplied to the split filter unit 219 and is subjected to band splitting. Resulting audio data is supplied to the frequency conversion unit 220. The frequency conversion unit 220 converts the audio data supplied from the split filter unit 219 into frequency information, and supplies the frequency information to the time conversion unit 223 and also to the duplication generation unit 282 via the switch 323 and the node 276.

Then, the duplication generation unit 282 generates high-range components using the fold-back scheme using the frequency information supplied from the frequency conversion unit 220, and supplies the high-range components to the shape adjustment unit 305 via the switch 328 and the node 293. The shape adjustment unit 305 adjusts the shape of the high-range components supplied from the duplication generation unit 282 using the extrapolation scheme, and supplies the shape-adjusted high-range components to the time conversion unit 222.

Further, the time conversion unit 222 converts the high-range components supplied from the shape adjustment unit 305 into audio data, and supplies the audio data to the combination filter unit 224. The time conversion unit 223 also converts the frequency information supplied from the frequency conversion unit 220 into audio data, and supplies the audio data to the combination filter unit 224. Then, the combination filter unit 224 combines the frequency bands of the audio data supplied from the time conversion unit 222 and the audio data supplied from the time conversion unit 223, and supplies resulting audio data to the output unit 144.

Accordingly, in addition to a band spreading method, each of a high-range-component generation method and a shape adjustment method can be changed to the most effective method in accordance with a classification result of a musical piece. The changed methods are used to generate high-range components and adjust the shape of the high-range components, resulting in more reliable improvement in quality of musical pieces (audio).

For example, when musical pieces are classified into types of musical pieces, that is, musical classes which represent categories such as jazz music or classical music, a high-range-component generation method or a shape adjustment method is changed for each musical class. Therefore, the sound quality improved.

Specifically, musical pieces in a musical class which represents classical music, that is, musical pieces classified as classical music, have a feature of including a large number of low-range components but including substantially no high-range components. In this case, for example, a high-range-component generation method for generating high-range components to be added to a musical piece using middle-range components in the musical piece, and a shape adjustment method for performing shape adjustment so that the level of the generated high-range components can be kept low are selected, and band spreading is performed. Therefore, quality similar to that of the original musical piece can be achieved.

Furthermore, musical pieces in a musical class which represents rock music generally have a feature that frequency components, or frequency spectra, exist widely over the human visible range. In this case, for example, a high-range-component generation method for generating high-range components using middle-range components of a musical piece, and a shape adjustment method for performing shape adjustment so that the power profile of the generated high-range components can be formed along the distribution of the power profile of the low- and middle-range components in the frequency domain are selected, and band spreading is performed. Therefore, the quality similar to that of the original musical piece can be achieved.

Accordingly, since the features of musical pieces differ for every musical class, a combination of a band spreading method, a high-range-component generation method, and a shape adjustment method, which is the most effective to improve sound quality, is recorded for each musical class. Band spreading is performed using a suitable combination of methods in accordance with a musical class. This provides more reliable improvement in quality of musical pieces.

In the foregoing description, a band spreading method, a high-range-component generation method, and a shape adjustment method are selectable in accordance with a classification result of a musical piece. Alternatively, those methods can be individually specified by a user.

In this case, for example, when a user specifies a band spreading method by operating the audio playback apparatus 131, an operation signal corresponding to the operation performed by the user is supplied to the switching unit 183. Then, the switching unit 183 switches the output of the audio data to one of the nodes 184 to 186 preferentially in response to the operation signal supplied in accordance with the operation performed by the user, rather than an instruction sent from the switching control unit 182, in accordance with the band spreading method specified by the operation signal.

When a user also specifies a high-range-component generation method, the switching unit 271 switches the output to one of the switches 321 to 323 preferentially in response to an operation signal supplied in accordance with the operation performed by the user, rather than an instruction sent from the switching control unit 182, in accordance with the high-range-component generation method specified by the operation signal and the band spreading method that has been selected.

When a user further specifies a method for adjusting the shape of the high-range components, the switching unit 284 switches the output to one of the switches 324 to 329 preferentially in response to an operation signal supplied in accordance with the operation performed by the user, rather than an instruction sent from the switching control unit 182, in accordance with the shape adjustment method specified by the operation signal and the band spreading method and high-range-component generation method that have been selected.

In this manner, by allowing a user to select a band spreading method, a high-range-component generation method, and a shape adjustment method as desired, a combination of a band spreading method, a high-range-component generation method, and a shape adjustment method, which is the most effective for the user, can be used to perform band spreading.

As described above, a combination of a band spreading method, a high-range-component generation method, and a shape adjustment method, which is recorded for each musical class on the band-spreading matching database, is obtained by statistically processing objective and subjective evaluation results. This does not ensure that such combinations of the methods for individual musical classes are not necessarily the most effective for all users to improve sound quality.

Furthermore, a user does not feel that an identical combination of methods is the most effective to improve sound quality all the time. In some cases, the user may wish to change his/her mood and to listen to different sound.

To meet this demand, a flexible configuration that allows a user to individually specify a band spreading method, a high-range-component generation method, and a shape adjustment method may be realized. This facilitates band spreading using a band spreading method, a high-range-component generation method, or a shape adjustment method, which is optimum for the user each time. This configuration can also meet a user's personal, emotional demand such as changing his/her mood and performing band spreading using a band spreading method different from usual.

Furthermore, in the correction unit 143 shown in FIG. 13, duplication generation units configured to generate high-range components using an identical high-range-component generation method are provided for individual band spreading methods. Alternatively, duplication generation units configured to generate high-range components using different methods may be provided for individual band spreading methods.

Specifically, in the correction unit 143, the duplication generation units 278 and 279 configured to generate high-range components using the fold-back scheme and the translating scheme, respectively, are provided for the frequency-based band spreading scheme. Further, the duplication generation units 280 and 281 configured to generate high-range components using the fold-back scheme and the translating scheme, respectively, are provided for the time-based band spreading scheme. For example, the duplication generation units 280 and 281 may be configured to generate high-range components using schemes different from the fold-back scheme and the translating scheme.

In the correction unit 143, similarly, shape adjustment units configured to perform shape adjustment using an identical shape adjustment method are provided for individual band spreading methods and high-range-component generation methods. Alternatively, shape adjustment units configured to perform shape adjustment using different shape adjustment methods may be provided for individual combinations of band spreading methods and high-range-component generation methods.

Further, the correction unit 143 shown in FIG. 13 includes a plurality of shape adjustment units that are configured to perform shape adjustment using an identical method and a plurality of duplication generation units that are configured to generate high-range components using an identical method. Alternatively, some of the shape adjustment units and some of the duplication generation units may be shared.

Specifically, for example, the switch 325 is configured to be connected to the shape adjustment unit 299 or the shape adjustment unit 300. Alternatively, the switch 325 may be connected to the shape adjustment unit 297 or the shape adjustment unit 298, which performs shape adjustment using the same method as that of the shape adjustment unit 299 or the shape adjustment unit 300. In this case, the shape adjustment unit 299 and the shape adjustment unit 300 in the correction unit 143 are no longer necessary, and the size of the correction unit 143 can be reduced.

In this configuration, high-range components are not output from the switches 324 and 325 at the same time. Thus, a plurality of types of high-range components are not input to one shape adjustment unit at the same time. The sharing of some shape adjustment units or duplication generation units enables efficient construction of the overall structure of the correction unit 143. A reduction in the size of the correction unit 143 can also be achieved.

The series of processes described above can be executed by hardware and software. When the series of processes is executed by software, a program constituting the software is installed into a computer incorporated in dedicated hardware or a device capable of implementing various functions by installing therein various programs, such as a general-purpose personal computer, from a network or a program recording medium.

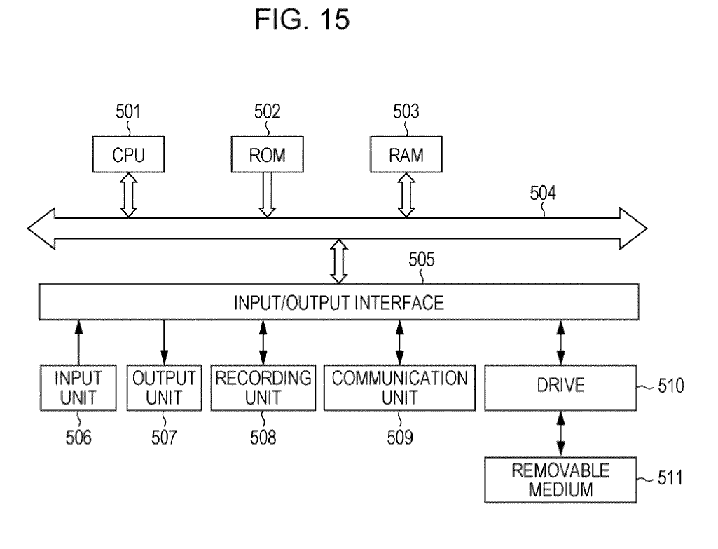

FIG. 15 is a block diagram showing an example hardware configuration of a computer that executes the series of processes described above according to a program.

In the computer, a central processing unit (CPU) 501, a read only memory (ROM) 502, and a random access memory (RAM) 503 are connected to one another via a bus 504.

An input/output interface 505 is also connected to the bus 504. The input/output interface 505 is connected to an input unit 506 including a keyboard, a mouse, and a microphone, an output unit 507 including a display and speakers, a recording unit 508 including a hard disk and a non-volatile memory, a communication unit 509 including a network interface, and a drive 510 for driving a removable medium 511 such as a magnetic disk, an optical disk, a magneto-optical disk, or a semiconductor memory.

In the computer having the configuration described above, the CPU 501 loads a program recorded in, for example, the recording unit 508 onto the RAM 503 via the input/output interface 505 and the bus 504 and executes the program. Accordingly, the series of processes described above is performed.

The program executed by the computer (the CPU 501) may be recorded on the removable medium 511, which is a package medium, such as a magnetic disk (including a flexible disk), an optical disk (such as a compact disc-read only memory (CD-ROM) or a digital versatile disc (DVD)), a magneto-optical disk, or a semiconductor memory, or may be provided through a wired or wireless transmission medium such as a local area network, the Internet, or digital satellite broadcasting.

The program can be installed onto the recording unit 508 through the input/output interface 505 by placing the removable medium 511 in the drive 510. Alternatively, the program can be received by the communication unit 509 via a wired or wireless transmission medium and installed onto the recording unit 508. In addition, the program can also be installed in advance in the ROM 502 or the recording unit 508.

The program executed by the computer may be a program for allowing processes to be performed in a time-series manner in accordance with the order described herein, or may be a program for allowing processes to be performed in parallel or at a desired time such as when the program is called.

Embodiments of the present invention are not limited to the foregoing embodiment, and a variety of modifications can be made without departing from the scope of the present invention.

The present application contains subject matter related to that disclosed in Japanese Priority Patent Application JP filed in the Japan Patent Office on Jun. 13, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An information processing apparatus comprising:
band spreading means for performing a band spreading process for generating components in a specific frequency band and adding the components to audio data; and
control means for controlling the band spreading means to execute the band spreading process using a band spreading method determined among a plurality of different band spreading methods, the band spreading method being defined in advance for a musical class determined-using a feature of the audio data.

2. The information processing apparatus according to claim 1, wherein the band spreading means performs a band spreading process for generating components in the specific frequency band based on audio data obtained by decoding encoded audio data and adding the components to the audio data.

3. The information processing apparatus according to claim 2, wherein the plurality of different band spreading methods include at least a band spreading method for performing the band spreading process along a time axis, a band spreading method for performing the band spreading process along a frequency axis, and a band spreading method for performing the band spreading process along the time axis and the frequency axis.

4. The information processing apparatus according to claim 3, wherein the audio data is data for playing back a musical piece, and
wherein the information processing apparatus further comprises classifying means for classifying the musical piece into one of a plurality of musical classes based on audio data of the musical piece, the plurality of musical classes being determined in advance using features of musical pieces.

5. The information processing apparatus according to claim 4, wherein the band spreading means includes
generating means for generating components in the specific frequency band using the audio data, and
adjusting means for increasing or decreasing each of frequency components in the specific frequency band, and
wherein the control means controls the adjusting means to increase or decrease each of the frequency components using an adjustment method determined among a plurality of adjustment methods for adjusting the components in the specific frequency band, the adjustment method being determined in advance in accordance with a classification result obtained by the classifying means.

6. The information processing apparatus according to claim 5, wherein the control means controls the generating means to generate components in the specific frequency band using a generation method determined among a plurality of generation methods for generating components in the specific frequency band, the generation method being determined in advance in accordance with the classification result.

7. The information processing apparatus according to claim 6, further comprising recording means for recording, for each of the plurality of musical classes, information indicating a combination of methods that is assigned in advance a highest evaluation among a plurality of combinations of methods, the plurality of combinations of methods including the plurality of band spreading methods, the plurality of generation methods, and the plurality of adjustment methods,
wherein the band spreading method, the generation method, and the adjustment method are selected using the classification result and the recorded information, and
wherein the control means controls the band spreading means to perform the band spreading process using the selected band spreading method, generation method, and adjustment method.

8. The information processing apparatus according to claim 7, wherein the evaluation is obtained by statistically processing an objective evaluation result and a subjective evaluation result, the objective evaluation result being obtained by performing analysis of audio data obtained using the band spreading process.

9. An information processing method for an information processing apparatus, comprising the steps of:
performing a band spreading process for generating components in a specific frequency band and adding the components to audio data; and
performing control to execute the band spreading process using a band spreading method determined among a plurality of different band spreading methods, the band spreading method being defined in advance for a musical class determined using a feature of the audio data.

10. A program for causing a computer of an information processing apparatus to execute a process comprising the steps of:
performing a band spreading process for generating components in a specific frequency band and adding the components to audio data; and
performing control to execute the band spreading process using a band spreading method determined among a plurality of different band spreading methods, the band spreading method being defined in advance for a musical class determined using a feature of the audio data.

11. An information processing apparatus comprising:
a band spreading unit configured to perform a band spreading process for generating components in a specific frequency band and adding the components to audio data; and
a control unit configured to control the band spreading unit to execute the band spreading process using a band spreading method determined among a plurality of different band spreading methods, the band spreading method being defined in advance for a musical class determined using a feature of the audio data.
